(19) United States
(12) Patent Application Publication
(10) Pub. No.: US 2025/0291487 A1
(43) Pub. Date: Sep. 18, 2025

(54) System and Method for Generating Full Binary Tree Codebooks Using Only Integer Operations for Resource-Constrained Environments

(71) Applicant: AtomBeam Technologies Inc., Moraga, CA (US)

(72) Inventors: Julien Dersy, Guildford (GB); Joshua Cooper, Columbia, SC (US)

(21) Appl. No.: 19/227,448

(22) Filed: Jun. 3, 2025

Related U.S. Application Data
(63) Continuation-in-part of application No. 19/218,170, filed on May 23, 2025.
Application No. 19/218,170 is a continuation-in-part of application No. 19/212,660, filed on May 19, 2025.
Application No. 19/212,660 is a continuation-in-part of application No. 19/207,301, filed on May 13, 2025.
Application No. 19/207,301 is a continuation-in-part of application No. 18/520,473, filed on Nov. 27, 2023, now Pat. No. 12,373,101.
Application No. 18/520,473 is a continuation of application No. 18/295,238, filed on Apr. 3, 2023, now Pat. No. 11,928,335.
Application No. 18/295,238 is a continuation of application No. 17/974,230, filed on Oct. 26, 2022, now Pat. No. 11,687,241.
Application No. 17/974,230 is a continuation-in-part of application No. 17/884,470, filed on Aug. 9, 2022, now abandoned.
(60) Provisional application No. 63/232,050, filed on Aug. 11, 2021.

(51) Int. Cl. G06F 3/06; H03M 7/30

(52) U.S. Cl. CPC G06F 3/0608; G06F 3/0623; G06F 3/0659; G06F 3/067; H03M 7/6005; H03M 7/6011

(57) ABSTRACT

A system and methods for generating full binary tree codebooks for encoding data within one bit of the optimal expected word length using only integer operations. The system transforms the modified Shannon-Fano algorithm into an implementation requiring only additions, subtractions, multiplications, and bit shifts, eliminating floating-point operations entirely. By tracking occurrence counts directly, replacing logarithmic calculations with most significant bit position detection, and using bit shifts instead of division, the method enables codebook generation on ultra-low-power microcontrollers lacking floating-point units. The approach requires only four integer registers beyond the occurrence counters, maintains a full binary tree structure ensuring every bit pattern of a given length is a valid codeword, and achieves compression performance within one bit of optimal. This implementation extends advanced compression capabilities to billions of resource-constrained devices including IoT sensors, wearables, and embedded systems where power consumption and computational capacity are severely limited.

### CROSS-REFERENCE TO RELATED APPLICATIONS

Priority is claimed in the application data sheet to the following patents or patent applications, each of which is expressly incorporated herein by reference in its entirety:
Ser. No. 19/218,170
Ser. No. 19/212,660
Ser. No. 19/207,301
Ser. No. 18/520,473
Ser. No. 18/295,238
Ser. No. 17/974,230
Ser. No. 17/884,470
63/232,050

### BACKGROUND OF THE INVENTION

### Field of the Invention

The present invention is in the field of data compression and encoding optimization, particularly relating to predictive performance analysis of entropy encoding methods, real-time codebook evaluation techniques, and resource-efficient implementation of compression algorithms for diverse computing environments.

### Discussion of the State of the Art

Current codebook generation systems typically create multiple codebooks for different sourceblock lengths, evaluate their performance through test encoding operations, and then select the best-performing configuration. This process is computationally intensive, with the codebook generation representing orders of magnitude greater complexity than the actual encoding and decoding operations. Furthermore, this approach results in significant waste, as most of the generated codebooks are discarded after evaluation. For example, a common approach is to generate 25 codebooks for sourceblock lengths between 1 and 25 bytes, but retain only the single best-performing codebook, resulting in 96% of the computational effort being wasted.

Additionally, existing approaches to codebook optimization often struggle with the trade-off between codebook size and coverage. Comprehensive codebooks that encode all possible sourceblocks become prohibitively large as sourceblock length increases, while more compact codebooks that focus on frequently occurring patterns leave many sourceblocks unaddressed. This limitation has traditionally forced a choice between compression efficiency and practical implementation constraints.

What is needed is a system and methods for implementing full binary tree codebook generation on ultra-low-power computing platforms that lack floating-point capabilities.

### SUMMARY OF THE INVENTION

The inventor has developed a system and methods for generating full binary tree codebooks for encoding data within one bit of the optimal expected word length using only integer operations. The system transforms the modified Shannon-Fano algorithm into an implementation requiring only additions, subtractions, multiplications, and bit shifts, eliminating floating-point operations entirely. By tracking occurrence counts directly, replacing logarithmic calculations with most significant bit position detection, and using bit shifts instead of division, the method enables codebook generation on ultra-low-power microcontrollers lacking floating-point units. The approach requires only four integer registers beyond the occurrence counters, maintains a full binary tree structure ensuring every bit pattern of a given length is a valid codeword, and achieves compression performance within one bit of optimal. This implementation extends advanced compression capabilities to billions of resource-constrained devices including IoT sensors, wearables, and embedded systems where power consumption and computational capacity are severely limited.

According to a preferred embodiment, a method for generating a full binary tree codebook using only integer operations is disclosed, comprising the steps of: collecting integer occurrence counts for a plurality of sourceblocks from a data stream; sorting the plurality of sourceblocks by decreasing occurrence count using integer comparison operations; initializing integer tracking variables for cumulative probability tracking and normalization; for each sourceblock in the sorted plurality of sourceblocks: calculating a normalized occurrence value using integer multiplication and a normalization factor; determining a codeword length by: approximating a logarithmic calculation using most significant bit position detection; performing bit shift operations based on the detected bit positions; and determining a ceiling value using integer comparison operations; updating the integer tracking variables using addition operations and bit shifts; and calculating a next normalization factor using integer operations to maintain a full binary tree structure; generating a full binary tree codebook based on the determined codeword lengths, wherein the codebook is generated using only integer addition, subtraction, multiplication, and bit shift operations.

According to another preferred embodiment, a system for generating a full binary tree codebook using only integer operations, comprising: a processor without floating-point capabilities; a memory storing instructions that, when executed by the processor, cause the system to: collect integer occurrence counts for a plurality of sourceblocks from a data stream; sort the plurality of sourceblocks by decreasing occurrence count using integer comparison operations; initialize integer tracking variables for cumulative probability tracking and normalization; for each sourceblock in the sorted plurality of sourceblocks: calculate a normalized occurrence value using integer multiplication and a normalization factor; determine a codeword length by: approximating a logarithmic calculation using most significant bit position detection; performing bit shift operations based on the detected bit positions; and determining a ceiling value using integer comparison operations; update the integer tracking variables using addition operations and bit shifts; and calculate a next normalization factor using integer operations to maintain a full binary tree structure; generate a full binary tree codebook based on the determined codeword lengths, wherein the codebook is generated using only integer addition, subtraction, multiplication, and bit shift operations.

According to a further aspect, the method includes: approximating the logarithmic calculation comprises: determining a first most significant bit position in a first integer value; determining a second most significant bit position in a second integer value; calculating a bit position difference between the first and second most significant bit positions; and performing a bit shift operation based on the calculated difference. According to a further aspect, the method includes: performing a comparison operation between a bit-shifted value and an original value; and based on the comparison result, adding an integer value of one to the bit position difference to determine the ceiling value. According to a further aspect, the method includes updating the integer tracking variables comprises: calculating a power of two using a left bit shift operation based on the determined codeword length; and adding an integer value to a running sum using integer addition. According to a further aspect, the method includes calculating the next normalization factor comprises: performing integer subtraction to determine a remaining probability space; performing integer subtraction to determine a sum of remaining sourceblock probabilities; and calculating a ratio using integer operations without floating-point division.

According to a further aspect, the method requires at most four integer registers beyond the occurrence counters for operation. According to a further aspect, the method is implemented on a microcontroller without a floating-point unit. According to a further aspect, the method includes: representing the codebook in a canonical form where only the codeword length for each sourceblock is stored. According to a further aspect, the method produces codeword lengths that are within one bit of the information-theoretic optimal length while using only integer operations.

### BRIEF DESCRIPTION OF THE DRAWING FIGURES

The accompanying drawings illustrate several aspects and, together with the description, serve to explain the principles of the invention according to the aspects. It will be appreciated by one skilled in the art that the particular arrangements illustrated in the drawings are merely exemplary and are not to be considered as limiting of the scope of the invention or the claims herein in any way.

FIG. 1 is a diagram showing an embodiment of the system in which all components of the system are operated locally.

FIG. 2 is a diagram showing an embodiment of one aspect of the system, the data deconstruction engine.

FIG. 3 is a diagram showing an embodiment of one aspect of the system, the data reconstruction engine.

FIG. 4 is a diagram showing an embodiment of one aspect of the system, the library management module.

FIG. 5 is a diagram showing another embodiment of the system in which data is transferred between remote locations.

FIG. 6 is a diagram showing an embodiment in which a standardized version of the sourceblock library and associated algorithms would be encoded as firmware on a dedicated processing chip included as part of the hardware of a plurality of devices.

FIG. 7 is a diagram showing an example of how data might be converted into reference codes using an aspect of an embodiment.

FIG. 8 is a method diagram showing the steps involved in using an embodiment to store data.

FIG. 9 is a method diagram showing the steps involved in using an embodiment to retrieve data.

FIG. 10 is a method diagram showing the steps involved in using an embodiment to encode data.

FIG. 11 is a method diagram showing the steps involved in using an embodiment to decode data.

FIG. 12 is a diagram showing an exemplary system architecture, according to a preferred embodiment of the invention.

FIG. 13 is a diagram showing a more detailed architecture for a customized library generator.

FIG. 14 is a diagram showing a more detailed architecture for a library optimizer.

FIG. 15 is a diagram showing a more detailed architecture for a transmission and storage engine.

FIG. 16 is a method diagram illustrating key system functionality utilizing an encoder and decoder pair.

FIG. 17 is a method diagram illustrating possible use of a hybrid encoder/decoder to improve the compression ratio.

FIG. 18 is an exemplary system architecture of a data encoding system used for data mining and analysis purposes.

FIG. 19 is an exemplary system architecture of a data encoding system used for remote software and firmware updates.

FIG. 20 is an exemplary system architecture of a data encoding system used for large-scale software installation such as operating systems.

FIG. 21 is a block diagram of an exemplary system architecture of a codebook training system for a data encoding system, according to an embodiment.

FIG. 22 is a block diagram of an exemplary architecture for a codebook training module, according to an embodiment.

FIG. 23 is a block diagram of another embodiment of the codebook training system using a distributed architecture and a modified training module.

FIG. 24 is a block diagram of an exemplary system architecture of a real-time codebook generation system for a data encoding system

FIG. 25 is a block diagram of an exemplary implementation of the real-time codebook generation system as an application-specific integrated circuit (ASIC), extending the FPGA implementation.

FIG. 26 is a block diagram of an exemplary FPGA implementation of the real-time codebook generation system, according to an embodiment.

FIG. 27 is a flow diagram illustrating an exemplary method for determining the compression performance of codebooks to be issued based on collected occurrences of symbols without issuing a single codebook, according to an embodiment.

FIG. 28 is a flow diagram illustrating an exemplary method for tracking in real-time the compression performance of codebooks to be issued as the sampling window moves without issuing a single codebook, according to an embodiment.

FIG. 29 is a flow diagram illustrating an exemplary method for generating a full binary tree codebook for encoding data within one bit of the optimal expected word length, according to an embodiment.

FIG. 30 is a flow diagram illustrating an exemplary method for determining when a secondary codebook should be used in conjunction with a primary codebook to optimize compression performance, according to an embodiment.

FIG. 31 is a flow diagram illustrating an exemplary method for determining compression performance of codebooks using integer-only calculations in resource-constrained computing environments, according to an embodiment.

FIG. 32 is a flow diagram illustrating an exemplary method for determining the compression performance of a hybrid codebook system using only integer operations and bit manipulations, according to an embodiment.

FIG. 33 illustrates an exemplary computing environment on which an embodiment described herein may be implemented, in full or in part.

### DETAILED DESCRIPTION OF THE DRAWING FIGURES

The inventor has conceived, and reduced to practice, a system and methods for generating full binary tree codebooks for encoding data within one bit of the optimal expected word length using only integer operations. The system transforms the modified Shannon-Fano algorithm into an implementation requiring only additions, subtractions, multiplications, and bit shifts, eliminating floating-point operations entirely. By tracking occurrence counts directly, replacing logarithmic calculations with most significant bit position detection, and using bit shifts instead of division, the method enables codebook generation on ultra-low-power microcontrollers lacking floating-point units. The approach requires only four integer registers beyond the occurrence counters, maintains a full binary tree structure ensuring every bit pattern of a given length is a valid codeword, and achieves compression performance within one bit of optimal. This implementation extends advanced compression capabilities to billions of resource-constrained devices including IoT sensors, wearables, and embedded systems where power consumption and computational capacity are severely limited.

Entropy encoding methods (also known as entropy coding methods) are lossless data compression methods which replace fixed-length data inputs with variable-length prefix-free codewords based on the frequency of their occurrence within a given distribution. This reduces the number of bits required to store the data inputs, limited by the entropy of the total data set. The most well-known entropy encoding method is Huffman coding, which will be used in the examples herein.

Because any lossless data compression method must have a code length sufficient to account for the entropy of the data set, entropy encoding is most compact where the entropy of the data set is small. However, smaller entropy in a data set means that, by definition, the data set contains fewer variations of the data. So, the smaller the entropy of a data set used to create a codebook using an entropy encoding method, the larger is the probability that some piece of data to be encoded will not be found in that codebook. Adding new data to the codebook leads to inefficiencies that undermine the use of a low-entropy data set to create the codebook.

This disadvantage of entropy encoding methods can be overcome by mismatch probability estimation, wherein the probability of encountering data that is not in the codebook is calculated in advance, and a special “mismatch codework” is incorporated into the codebook (the primary encoding algorithm) to represent the expected frequency of encountering previously-unencountered data. When previously-unencountered data is encountered during encoding, attempting to encode the previously-unencountered data results in the mismatch codeword, which triggers a secondary encoding algorithm to encode that previously-unencountered data. The secondary encoding algorithm may result in a less-than-optimal encoding of the previously-unencountered data, but the efficiencies of using a low-entropy primary encoding make up for the inefficiencies of the secondary encoding algorithm. Because the use of the secondary encoding algorithm has been accounted for in the primary encoding algorithm by the mismatch probability estimation, the overall efficiency of compaction is improved over other entropy encoding methods.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in the one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only, and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of the more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

The term “bit” refers to the smallest unit of information that can be stored or transmitted. It is in the form of a binary digit (either 0 or 1). In terms of hardware, the bit is represented as an electrical signal that is either off (representing 0) or on (representing 1).

The term “byte” refers to a series of bits exactly eight bits in length.

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless,” in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio,” and as used herein all mean the size of the original data relative to the size of the compressed data (e.g., if the new data is 70% of the size of the original, then the deflation/compression ratio is 70% or 0.7.)

The term “data” means information in any computer-readable form.

The term “data set” refers to a grouping of data for a particular purpose. One example of a data set might be a word processing file containing text and formatting information.

The term “effective compression” or “effective compression ratio” refers to the additional amount data that can be stored using the method herein described versus conventional data storage methods. Although the method herein described is not data compression, per se, expressing the additional capacity in terms of compression is a useful comparison.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1 megabyte sourcepacket of data may be encoded using 512 byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code or “codeword” to a sourceblock in the library plus an indication of that sourceblock's location in a particular data set.

The term “full binary tree codebook” as used herein refers to an entropy encoding codebook structure where every possible bit pattern of a given length represents a valid codeword, simplifying encoding and decoding operations.

The term “hybrid codebook system” as used herein refers to a two-tier encoding approach using a primary codebook with longer sourceblocks for common patterns and a secondary codebook with shorter sourceblocks for handling mismatches.

The term “mismatch probability” as used herein refers to the probability that a sourceblock encountered during encoding will not match any sourceblock in the primary codebook, requiring fallback to a secondary encoding method.

### Conceptual Architecture

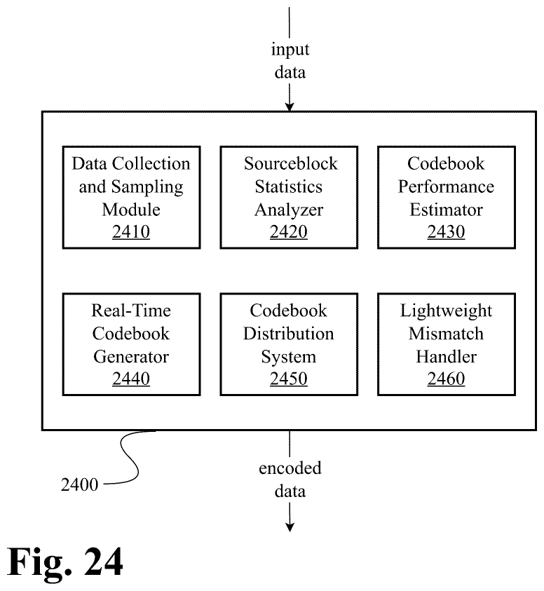

FIG. 24 is a block diagram of an exemplary system architecture 2400 of a real-time codebook generation system for a data encoding system. According to this embodiment, the real-time codebook generation system 2400 comprises several interconnected components that efficiently generate and optimize codebooks without requiring the substantial computational resources of traditional methods. The system 2400 includes a data collection and sampling module 2410, a sourceblock statistics analyzer 2420, a codebook performance estimator 2430, a real-time codebook generator 2440, a codebook distribution system 2450, and a lightweight mismatch handler 2460. The system 2400 further supports multiple implementation variations including a resource-constrained implementation, an FPGA implementation, and a cloud/server implementation.

The data collection and sampling module 2410 receives input data streams and implements various sliding window sampling techniques to efficiently track sourceblock occurrences. Module 2410 maintains occurrence statistics including counters for individual sourceblock occurrences, referred to herein as O(j) for the number of occurrences measured for sourceblock j, and total occurrences (TO) across the sampling window. Officially, TO can be defined as:

$$T O = {\sum }_{i = 1}^{q} O ( i )$$

For a fixed sampling window the TO value can be considered the same for all n-bytes sourceblock sampling, with a margin of error of n/TO, wherein the sampling may be performed by shifting the sampling window by one byte for all n-bytes sourceblocks. As new data arrives, module 2410 efficiently updates these statistics using minimal computational resources, making it suitable for deployment in resource-constrained environments. The sliding window approach allows the system to adapt to changing data patterns over time without requiring complete reanalysis of historical data.

The sourceblock statistics analyzer 2420 receives occurrence data from module 2410 and calculates probability values P(j) for each sourceblock as the ratio of sourceblock occurrences O(j) (variables i and j may be used interchangeably herein to represent a particular instance/measurement of a given statistical property) to total occurrences TO:

$$P ( j ) = \frac{O ( j )}{T O}$$

Analyzer 2420 computes the sum of squared probabilities (Q value) which serves as a key metric for estimating compression performance. For Markovian data distributions, this Q value can be calculated as:

$$Q = {\sum }_{i = 1}^{q} P {( i )}^{2}$$

or equivalently as:

$$Q = \frac{{\sum }_{i = 1}^{q} O {( i )}^{2}}{T {O}^{2}}$$

Analyzer 2420 further estimates mismatch probability (Pₘᵢₛ) representing the likelihood that a sourceblock will not be found in the codebook. In some aspects, analyzer 2420 can be configured to operate using only integer-based calculations, including additions, subtractions, and bit shifts, avoiding floating-point operations that would require additional computational resources.

According to an embodiment, analyzer 2420 can be configured to calculate probability mismatch Pₘᵢₛ and observation mismatch (Oₘᵢₛ). These related expressions may be represented as:

$${P}_{mis} = 1 - {\sum }_{i = 1}^{q} {P}^{′} ( i )$$

$${O}_{mis} = TO - {\sum }_{i = 1}^{q} O ( i )$$

The codebook performance estimator 2430 calculates expected compaction performance for different sourceblock lengths without generating actual test codebooks. Estimator 2430 calculates the compaction factor K as:

$$K = - \frac{{log}_{2} ( Q )}{n * 8}$$

where a smaller K value indicates better performance. For fixed sourceblock length n, larger Q values represent better potential performance. Estimator 2430 further determines the combined performance of primary and secondary codebooks (when applicable) by calculating:

$${K}_{comb} = ( 1 - {P}_{mis} ) \cdot {K}_{prim} + {P}_{mis} \cdot ( {K}_{2 nd} + ⌈ \frac{- {log}_{2} ( {P}_{mis} )}{n \cdot 8} ⌉ )$$

Wherein: Kₚᵣᵢₘ is the K value of the primary n-bytes long q sourceblocks of probability Pₚᵣᵢₘ(j) such that the sum of all Pₚᵣᵢₘ=1; K_{2nd} is the K value of the secondary 1-byte sourceblocks; by using canonical Huffman coding, secondary 1-byte codebook is always of size 256 bytes, 1-byte for each symbol to encode the length of the codework. Using canonical Huffman coding the size of the primary codebook upper bound in bytes is:

$$q \cdot n + q \cdot ⌈ \frac{{log}_{2} ( q )}{8} ⌉$$

Therefore the top q sourceblocks can be selected to meet codebook size requirements (note: q*n is the size of sourceblocks in the codebook and ceil [(log₂(q)/8)] is the number of bytes needed to encode the codeword length. This analysis allows the system to identify optimal sourceblock lengths and estimate compaction performance without the computational expense of generating and testing multiple codebooks. In the combined K value equations −log₂(Pₘᵢₛ) represents the length of the mismatch codeword added to the secondary encoding. The best value of n can then be selected for issuing the codebook. With:

$$m = ⌈ - {log}_{2} ( P ) ⌉$$

such that:

$$\frac{1}{{2}^{m}} \leq P or \frac{1}{{2}^{m}} \leq \frac{O}{TO} or \frac{TO}{{2}^{m}} \leq O$$

Therefore m is the smallest number of bit-shifts right of TO such that the result is less than or equal to O (using standard MSB-first binary encoding). It is therefore possible to transform the algorithms described herein to operate only with additions, subtractions, and bit-shift operations, according to various embodiments.

According to some embodiments, real-time codebook generator 2440 can be configured to implement a modified Shannon-Fano algorithm for codeword length assignment, creating full binary tree codebooks with minimal computational resources. In such embodiments, generator 2440 produces codeword lengths that are always within one bit of the optimal expected word length while requiring significantly less memory and processing power than traditional Huffman coding approaches. The algorithm normalizes probabilities to redistribute “lost” probability from frequent symbols and calculates codeword lengths m(i) using only integer operations. As a result, generator 2440 can operate with only four integer registers in addition to the sourceblock occurrence counters, making it suitable for highly resource-constrained environments.

The codebook distribution system 2450 packages optimized codebooks for distribution to encoders and decoders throughout the network. Codebook distribution system 2450 implements versioning to track codebook updates, manages the delivery of both primary and secondary codebooks to endpoints, and tracks deployment metrics to ensure proper synchronization across the network. System 2450 may selectively distribute codebooks based on performance metrics (or some other criteria), ensuring that only significant improvements trigger full network updates, thereby reducing bandwidth utilization and system disruption.

The lightweight mismatch handler 2460 efficiently processes sourceblocks not found in the primary codebook. Handler 2460 implements a secondary encoding method optimized based on measured mismatch probabilities. For canonical Huffman coding, the secondary 1-byte codebook remains a constant size of 256 bytes, with 1-byte for each symbol to encode the length of the codeword. Handler 2460 operates with minimal computational overhead, ensuring that mismatch situations do not significantly degrade overall system performance even in resource-constrained environments.

System 2400 supports multiple implementation variations tailored to different deployment scenarios. A resource-constrained implementation can be optimized for devices with limited processing capabilities, such as ARM Cortex-M0/M3 processors without floating-point units. Implementation uses exclusively integer-based calculations and minimizes memory footprint, making it suitable for wearables, sensors, and IoT devices. An FPGA implementation parallelizes sourceblock frequency calculations, implements dedicated hardware for bit-shift operations and integer arithmetic, and uses specialized memory structures for efficient codebook generation. Implementation provides hardware acceleration for the modified Shannon-Fano algorithm, enabling high-performance operation with minimal power consumption. A cloud/server implementation handles multiple data streams concurrently, maintains separate codebooks for different data types or sources, and implements more sophisticated statistical analysis for optimizing codebooks. Implementation provides centralized codebook management for distributed encoder/decoder networks, enabling enterprise-scale deployment.

The real-time codebook generation system 2400 is designed with flexibility to accommodate various implementation environments, from high-performance cloud servers to highly resource-constrained devices. In resource-constrained implementations, such as ASIC or FPGA embodiments, the system may comprise more or fewer components than those described in system 2400, and the functionality of certain components may be combined, simplified, or otherwise altered to optimize for the specific constraints of these environments. For example, in an ASIC implementation, the sourceblock statistics analyzer 2420 and codebook performance estimator 2430 functionalities might be combined into a single optimized circuit to reduce silicon area, while in an FPGA implementation, the real-time codebook generator 2440 might be implemented with reduced pipeline stages to conserve logic resources. These adaptations enable the core algorithms and methodologies of the invention to be deployed across a wide spectrum of computing platforms, from powerful server clusters to low-power embedded devices, while maintaining the essential performance benefits of real-time codebook generation and optimization.

As data patterns evolve over time, the real-time codebook generation system 2400 continuously monitors performance metrics and adaptively updates codebooks as needed. This approach eliminates the computational waste of traditional codeword methods, which is limited by the codebook generation step(s). System 2400 achieves near-optimal compression performance while requiring only a fraction of the computational resources, making efficient data compaction feasible even on highly resource-constrained devices.

According to an embodiment, cloud/server implementation leverages the computational resources available in data center environments to provide enhanced functionality beyond what's possible in resource-constrained or FPGA implementations. Unlike the resource-constrained implementations that prioritize minimal computing requirements, the cloud/server implementation can utilize available processing power to handle multiple data streams concurrently and implement more sophisticated statistical analysis techniques.

A feature of the cloud/server implementation is its ability to maintain separate codebooks for different data types or sources. When receiving data from diverse origins-such as IoT sensors with varying characteristics, multimedia streams, or different application logs-the system can recognize patterns specific to each data type and generate optimized codebooks accordingly. This multi-tenant architecture allows for fine-grained optimization that recognizes the unique statistical properties of different data sources rather than applying a one-size-fits-all approach.

The implementation employs advanced statistical modeling techniques that may be too computationally intensive for edge devices. These include, but are not limited to, Bayesian probability models to better predict the likelihood of encountering new sourceblocks, clustering algorithms to identify patterns across multiple data streams, and machine learning approaches to anticipate changes in data distributions. By implementing these techniques, the system can generate codebooks that more accurately reflect the statistical properties of the data, resulting in improved compression ratios.

For enterprise deployments, the cloud/server implementation provides centralized codebook management for distributed encoder/decoder networks. This centralized approach ensures consistency across the entire system, with all encoders and decoders using compatible codebooks. When a codebook update is generated, the distribution system can coordinate the deployment of the update to all affected devices, ensuring synchronized operation across the network. This is particularly important in large-scale systems where maintaining consistency between thousands of devices would otherwise be challenging.

The cloud/server implementation can also implement advanced scheduling algorithms for codebook updates. Rather than updating codebooks based solely on performance metrics, the system can consider network conditions, device status, and operational patterns to schedule updates during periods of low activity or when bandwidth constraints are minimized. This intelligent scheduling reduces the impact of codebook updates on ongoing operations.

Additionally, the cloud/server implementation can store historical performance data and codebook versions, enabling rollback capabilities if a new codebook unexpectedly performs poorly in real-world conditions. This versioning system provides a safety net for enterprise deployments where reliability is critical.

The implementation also offers integration with existing data analytics platforms, allowing organizations to monitor compression performance as part of their overall data management strategy. Performance metrics such as compression ratio, encoding/decoding throughput, and mismatch frequency can be exported to dashboard systems, providing visibility into the system's operation and helping to identify opportunities for further optimization.

In large-scale deployments, the cloud/server implementation can be distributed across multiple physical servers or virtualized environments to ensure both scalability and redundancy. Load balancing mechanisms distribute the workload of codebook generation and management across available resources, while failover capabilities ensure continued operation even if individual components fail.

According to an embodiment, real-time codebook generation system 2400 further implements an adaptive codebook switching mechanism as a subcomponent of codebook distribution system 2540 that optimizes compression performance while minimizing computational overhead. The adaptive codebook switching mechanism dynamically determines when to switch between codebooks of different sourceblock lengths based on continuously monitored compression performance metrics.

In operation, the codebook performance estimator 2430 calculates a first compaction factor Kₚᵣᵢₘ for a primary codebook having sourceblocks of a first length n bytes, where n is typically optimized for the specific data type being processed. Simultaneously, the estimator 2430 calculates a second compaction factor K_{2nd} for a secondary codebook having sourceblocks of a second length, typically (but not limited to) 2 bytes, which provides a balance between compression efficiency and computational simplicity. The adaptive codebook switching mechanism 2495 then determines a compaction performance delta ΔK between Kₚᵣᵢₘ and K_{2nd}, representing the potential improvement in compression performance that would be achieved by switching from one codebook to the other.

A threshold evaluator component within the adaptive switching mechanism compares this performance delta ΔK against a predetermined threshold value t. This threshold value may be statically configured based on application requirements or dynamically adjusted based on available computational resources and current system load. When the performance delta exceeds the threshold (ΔK>τ), the system triggers a codebook selection operation that selects the codebook with the superior compression performance for subsequent encoding operations.

This threshold-based approach significantly reduces the computational overhead of the system by preventing unnecessary codebook switching when the potential compression improvement would be marginal. For example, in a typical implementation processing sensor data, the threshold τ might be set to 0.05, representing a 5% improvement in compression ratio. With this threshold, the system would only switch codebooks when doing so would yield at least a 5% improvement in data size reduction, thereby avoiding the computational cost of frequent switching for minimal gain.

The adaptive codebook switching mechanism may further incorporate a hysteresis component that prevents rapid oscillation between codebooks when the performance delta hovers near the threshold value. This hysteresis mechanism requires that the performance delta exceed the threshold by a certain margin before switching from the currently active codebook, and then requires that it fall below a separate threshold before switching back. This stabilizes the system's behavior in boundary conditions and further reduces computational overhead.

By integrating this adaptive switching capability, the real-time codebook generation system 2400 achieves an optimal balance between compression performance and computational efficiency across a wide range of data characteristics and operational conditions. This is particularly valuable in environments with fluctuating data patterns or constrained resources, where the trade-off between compression ratio and processing overhead must be continuously optimized.

According to an aspect of an embodiment, real-time codebook generation system 2400 further comprises an integer-only implementation module that enables deployment on highly resource-constrained devices lacking floating-point processing capabilities. This module transforms the mathematical operations required for compression performance estimation into equivalent operations using only integer arithmetic and bit manipulations, making the system viable for deployment on low-power microcontrollers commonly found in IoT devices, wearables, and embedded systems.

The integer-only implementation module specifically addresses the computational challenges in calculating the combined performance metric K_{comb} for a two-level codebook system. This calculation normally requires logarithmic operations and floating-point division, which can be prohibitively expensive on constrained hardware. Instead, the modified embodiment implements an equivalent calculation using the following approach:

For comparing the performance of different sourceblock lengths, the modified system computes:

$${TO}_{mis} \cdot 8 \cdot {K}_{comb}$$

where TOₘᵢₛ represents the total number of occurrences including mismatch occurrences (i.e., TOₘᵢₛ=TO+Oₘᵢₛ). This value can be expressed as:

$${TO}_{mis} \cdot 8 \cdot {K}_{comb} = ( {TO}_{mis} - {O}_{mis} ) \cdot ( - \frac{{log}_{2} ( {Q}_{prim} )}{n} ) + ( - {log}_{2} ( {Q}_{2 nd} ) \cdot {O}_{mis} ) + ( \frac{⌈ - {log}_{2} ( \frac{{O}_{mis}}{{TO}_{mis}} ) ⌉}{n} )$$

where Oₘᵢₛ represents the equivalent number of occurrences for mismatch codewords, Qₚᵣᵢₘ relates to the primary codebook's compaction factor, and Q_{2nd} relates to the secondary codebook's compaction factor. Such that:

$${K}_{prim} = \frac{- {log}_{2} ( {Q}_{2 nd} )}{8}$$

and wherein:

$${K}_{comb} = ( 1 - \frac{{O}_{mis}}{{TO}_{mis}} ) \cdot ( \frac{- {log}_{2} ( {Q}_{prim} )}{n \cdot 8} ) + \frac{{O}_{mis}}{{TO}_{mis}} \cdot ( \frac{- {log}_{2} ( {Q}_{2 nd} )}{8} + [ \frac{- {log}_{2} ( \frac{{O}_{mis}}{{TO}_{mis}} )}{n \cdot 8} ] )$$

The modified embodiment simplifies this calculation by normalizing TOₘᵢₛ and TO to be the same across all instances of n, keeping them constant once the sampling window has filled up. This ensures that TO² remains constant, as does log₂(TO²). The logarithmic operations can be implemented using optimized bit-shifting techniques, with −log₂(Qₚᵣᵢₘ) calculated by using:

$${log}_{2} ( {TO}^{2} ) - {log}_{2} ( {\sum }_{i = 1}^{q} {{O}_{prim} ( i )}^{2} )$$

For the ceiling of logarithmic values needed in certain calculations, the module employs a bit-manipulation approach using the most significant bits (MSB) of the operands. For example, to compute:

$$⌈ - {log}_{2} ( \frac{{O}_{mis}}{{TO}_{mis}} ) ⌉$$

the system may be configured to:
Perform [MSB(TOₘᵢₛ)−MSB(Oₘᵢₛ)] bit shifts right of TOₘᵢₛ
If the result is less than or equal to Oₘᵢₛ, then:

$$⌈ - {log}_{2} ( \frac{{O}_{mis}}{{TO}_{mis}} ) ⌉ = MSB ( {TO}_{mis} ) - MSB ( {O}_{mis} )$$

otherwise:

$$⌈ - {log}_{2} ( \frac{{O}_{mis}}{{TO}_{mis}} ) ⌉ = MSB ( {TO}_{mis} ) - MSB ( {O}_{mis} ) + 1$$

By constraining the total occurrences to be the same across all sampling values of n, the module enables direct comparison of performance metrics using primarily integer operations. This approach is further optimized by constraining n to powers of 2 (e.g., 1, 2, 4, 8, 16, etc.), which simplifies the required divisions to simple bit shifts.

The integer-only implementation module makes the real-time codebook generation system 2400 particularly well-suited for implementation on ultra-low-power hardware platforms such as ARM Cortex-M0/M0+ and M3 processors that lack floating-point units. This enables the deployment of sophisticated compression optimization on resource-constrained edge devices, bringing the benefits of real-time codebook generation to applications where processing power and energy consumption are critical constraints.

According to an aspect of an embodiment, real-time codebook generation system 2400 further comprises a hybrid codebook performance estimation module (which may be a sub-component/subsystem of codebook performance estimator 2430 or other system components) that evaluates the compression performance of a two-tier codebook architecture without generating test codebooks. This module addresses the challenge of balancing compression efficiency with codebook size constraints by enabling accurate estimation of performance when using an incomplete primary codebook that falls back to a complete secondary codebook for encoding sourceblocks not found in the primary codebook. The hybrid approach leverages the strengths of both larger sourceblock primary codebooks for capturing complex patterns and smaller secondary codebooks for handling edge cases, ultimately achieving superior compression performance across diverse data types.

The hybrid codebook performance estimation module may be configured to calculate a combined compaction factor K_{comb} that represents the performance of the primary/secondary codebook pair. This calculation incorporates the primary codebook's compaction factor Kₚᵣᵢₘ applied to the proportion of sourceblocks it can encode, the secondary codebook's compaction factor K_{2nd} applied to mismatched sourceblocks, and the overhead of including mismatch indicators. By using canonical Huffman coding, the module ensures predictable codebook sizes, with the secondary 1-byte codebook maintaining a constant size of 256 bytes and the primary codebook size bounded by:

$$q \cdot n \cdot q \cdot ⌈ \frac{{log}_{2} ( q )}{8} ⌉$$

where q is the number of sourceblocks and n is the sourceblock length in bytes.

According to an aspect, the module comprises the ability to estimate the mismatch probability Pₘᵢₛ without requiring codebook generation. This probability may be calculated either as the ratio of unrepresented sourceblocks to total sourceblocks or measured directly from occurrence counters as Oₘᵢₛ. This mismatch probability is important for accurately predicting the combined performance of the two-tier system, as it determines how frequently the system must fall back to the less efficient secondary encoding. The module leverages this probability to create an optimal balance between primary codebook size and comprehensive coverage, enabling selective inclusion of only the most frequent sourceblocks in the primary codebook while maintaining efficient encoding for all possible sourceblocks through the secondary fallback mechanism.

By providing accurate performance estimates for hybrid codebook configurations, the module enables intelligent codebook size optimization and selective sourceblock inclusion based on frequency, ultimately achieving compression performance that approaches theoretical limits while maintaining practical constraints on memory usage and computational complexity. This capability is particularly valuable in systems with limited memory resources, where codebook size must be carefully balanced against compression efficiency, and in applications processing diverse data types, where a single comprehensive codebook would be impractically large.

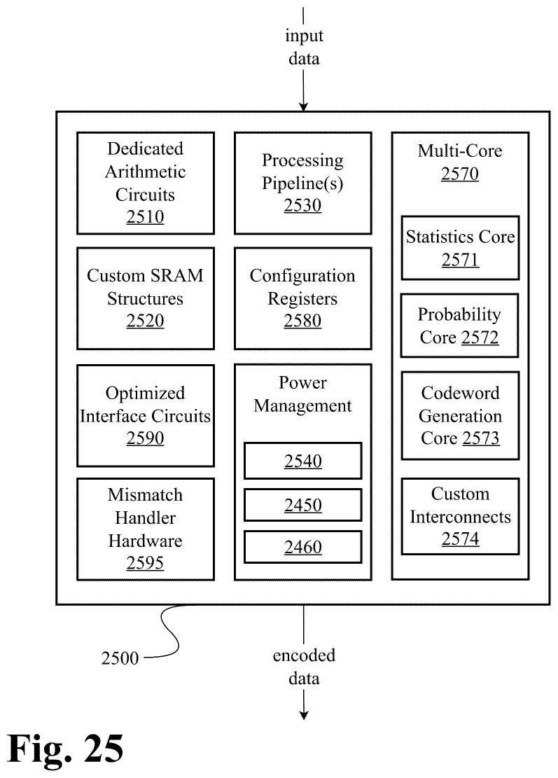

FIG. 25 is a block diagram of an exemplary implementation of the real-time codebook generation system as an application-specific integrated circuit (ASIC) 2500, extending the FPGA implementation. The ASIC implementation 2500 comprises highly optimized, fixed-function circuits specifically tailored to the codebook generation algorithms, achieving significantly higher performance with lower power consumption compared to the FPGA implementation. The bit-shift operations, integer additions, and probability calculations that form the core of the algorithm can be implemented using dedicated arithmetic circuits 2510 rather than programmed logic blocks, resulting in higher clock rates and reduced power consumption.

The ASIC implementation 2500 incorporates custom SRAM structures 2520 designed precisely for the access patterns required by the algorithm. These memory structures may include specialized memory banks for sourceblock occurrence tracking and codebook storage with optimized read/write ports configured for the specific data flow of the algorithm. This customized memory architecture eliminates the overhead associated with general-purpose memory configurations found in FPGAs, improving both access speed and energy efficiency.

A deeply pipelined architecture 2530 is specifically designed for the modified Shannon-Fano algorithm's data dependencies, with register stages placed at optimal boundaries to maximize throughput while maintaining the integer-only calculation requirements. This pipeline optimization enables sustained high-throughput processing of sourceblock statistics and codebook generation, significantly outperforming the reconfigurable pipeline structures available in FPGAs.

The ASIC implementation 2500 enables power efficiency through the implementation of only the specific circuits needed for the codebook generation algorithm. Advanced power management techniques including, but not limited to, clock gating circuits 2540, multiple power domains 2550, and dynamic voltage scaling 2560 are incorporated to further reduce energy consumption. These power optimization features are particularly important for battery-operated devices where power consumption is a critical constraint.

A multi-core architecture 2570 incorporates several processing cores optimized for different aspects of the codebook generation process. Dedicated cores for statistics gathering 2571, probability calculation 2572, and codeword generation 2573 operate in parallel, with custom interconnects 2574 optimized for the specific data flows between these operations. This parallel architecture enables higher throughput than would be possible with a single processing pipeline.

Configuration registers 2580 allow adjustment of operational parameters such as sourceblock length, sampling window size, and codebook update thresholds. These programmable elements preserve the adaptability of the system while maintaining the efficiency benefits of a custom hardware implementation. The configuration interface provides a mechanism for runtime adjustment of these parameters based on application requirements or data characteristics.

Optimized interface circuits 2590 implement standard protocols (such as SPI, I2C, or more advanced interfaces) for efficient data exchange with host systems. These interfaces are specifically designed to minimize communication overhead while providing the necessary bandwidth for data transfer between the ASIC and external systems.

The lightweight mismatch handler functionality can be implemented through dedicated hardware circuits 2595 for identifying and encoding mismatched sourceblocks using the secondary encoding method. This hardware acceleration eliminates the processing overhead associated with software-based mismatch handling, ensuring that mismatch situations do not significantly impact overall system performance.

The ASIC implementation 2500 delivers several advantages over the FPGA version, including reduced power consumption depending on the application, increased processing throughput for equivalent clock rates, smaller physical footprint, and lower unit cost at high volumes. These improvements make the technology economically viable for mass-market applications and enable integration into highly space-constrained devices. The ASIC implementation 2500 is particularly valuable for applications requiring extremely low power consumption or high-volume deployment, such as battery-powered IoT devices, implantable medical devices, or consumer electronics where efficient data compression provides significant system-level benefits.

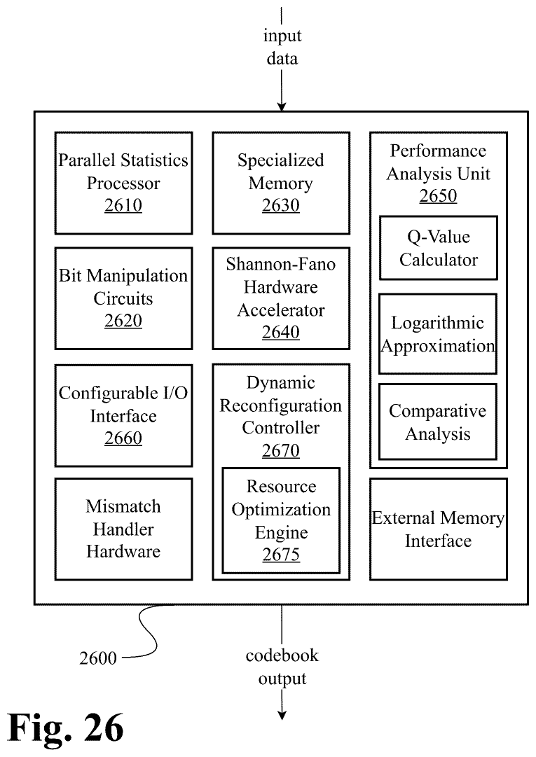

FIG. 26 is a block diagram illustrating an exemplary FPGA implementation of the real-time codebook generation system, according to an embodiment. The FPGA implementation 2600 provides a hardware-accelerated platform that significantly outperforms software-based implementations while maintaining greater flexibility than ASIC designs. This implementation leverages the reconfigurable nature of FPGA technology to create specialized circuits for codebook generation that can be updated as algorithms evolve, making it an ideal platform for both development and deployment.

The FPGA implementation comprises several functional blocks arranged in an optimized pipeline architecture to maximize throughput while minimizing latency. According to an aspect, the system comprises a parallel statistics processor 2610 that simultaneously processes multiple sourceblocks from the input data stream. This parallel architecture enables the FPGA to process data at a much higher rate than would be possible with sequential processing, with dedicated occurrence counters implemented directly in hardware for high-speed updates. The statistics processor 2610 leverages the FPGA's distributed memory resources to maintain occurrence counters for frequently observed sourceblocks, with less common sourceblocks tracked in external memory through optimized memory controllers.

The implementation includes dedicated bit manipulation circuits 2620 specifically optimized for the bit-shift operations central to the modified Shannon-Fano algorithm and performance estimation calculations. These circuits implement operations such as finding the most significant bit (MSB), counting leading zeros, and performing variable-length bit shifts, all of which are common operations in entropy coding but can be inefficient when implemented in general-purpose processors. By creating specialized circuits for these operations, the FPGA implementation achieves significantly higher performance with lower power consumption than software implementations.

According to an aspect, a component of the FPGA implementation is the specialized memory architecture 2630 designed specifically for the access patterns required by the codebook generation algorithms. This includes dual-port memory blocks for simultaneous read and write operations, content-addressable memory (CAM) for high-speed sourceblock lookups, and optimized memory controllers for efficient access to external memory. The memory architecture 2630 is carefully designed to minimize access latencies and maximize throughput, with buffer structures and caching mechanisms tailored to the specific data flow patterns of the codebook generation process.

The implementation incorporates a hardware accelerator 2640 for the modified Shannon-Fano algorithm, implementing the full codebook generation process in a pipelined architecture. This accelerator receives probability distributions from the statistics processor and outputs complete codebooks with minimal latency, enabling near-instantaneous codebook updates when performance metrics indicate that a new codebook would provide significant benefits. The pipelined architecture allows multiple stages of the Shannon-Fano algorithm to execute concurrently, maximizing throughput while maintaining the strict dependency relationships required by the algorithm.

A performance analysis unit 2650 continuously calculates compaction metrics based on the current probability distribution, without requiring the generation of test codebooks. This unit implements the mathematical calculations described in the real-time tracking method 2800, using hardware-optimized implementations of the required mathematical functions including logarithmic approximation circuits specifically designed for the compaction factor calculation. By implementing these calculations in hardware, the FPGA can continuously monitor potential codebook performance with minimal overhead, enabling intelligent scheduling of codebook updates.

The FPGA implementation also includes a configurable I/O interface 2660 that supports multiple communication protocols, allowing the system to integrate seamlessly with a wide range of host systems and data sources. This interface provides high-speed data paths for both input data streams and output codebooks, with configurable buffering to accommodate varying data rates and burst patterns. The interface supports standard protocols such as PCIe, Ethernet, and serial connections, as well as customized interfaces for specific applications such as sensor networks or storage systems.

A dynamic reconfiguration controller 2670 enables runtime optimization of the FPGA resources based on the characteristics of the data being processed. This controller can adjust parameters such as pipeline depth, memory allocation, and processing width to achieve the optimal balance of throughput, latency, and power consumption for a given application. For example, when processing highly compressible data with strong patterns, the controller might allocate more resources to codebook generation, while for more uniform data distributions, it might prioritize statistics gathering and performance analysis.

The FPGA implementation provides several significant advantages over software-based implementations, including higher throughput, lower latency, and reduced power consumption. Compared to the resource-constrained implementation, the FPGA can process data at rates 10-50× higher while consuming only marginally more power. This makes the FPGA implementation particularly well-suited for applications with high data rates or tight latency constraints, such as real-time multimedia processing, high-speed sensor networks, or enterprise storage systems. The reconfigurable nature of the FPGA also provides a development pathway toward eventual ASIC implementation 2500, allowing algorithms and architectures to be refined in a hardware environment before committing to fixed-function silicon.

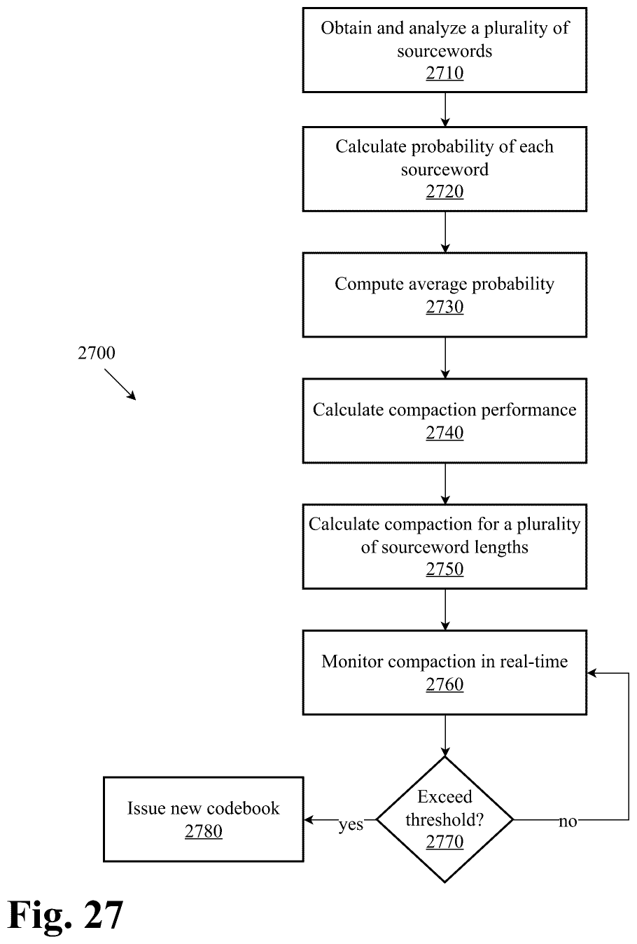

FIG. 27 is a flow diagram illustrating an exemplary method 2700 for determining the compression performance of codebooks to be issued based on collected occurrences of symbols without issuing a single codebook, according to an embodiment. The process leverages mathematical relationships between probability distributions and expected codebook performance in Huffman coding to predict compression ratios without the computational expense of generating and testing multiple codebooks. This represents a significant advancement over traditional approaches that require codebook generation and testing to determine performance metrics. The key insight in this method is that in Huffman coding, the bit length of a codeword for a symbol with probability P is approximately ceil(−log₂(P)) typically within 1 bit of accuracy, allowing for accurate performance prediction using only statistical analysis of the data.

The method 2700 begins with a data collection step 2710 where sourceblocks are collected and analyzed from the data stream. Several parameters may be measured and tracked, including n, the length in bytes of sourceblocks collected; q, the total number of unique sourceblocks collected; O(j), the number of occurrences measured for each sourceblock j; and TO, the total number of occurrences measured, calculated as the sum of all O(i) values. In a probability calculation step 3120, the method calculates P(j), the probability of occurrence for each sourceblock j, as the ratio O(j)/TO. This probability distribution forms the foundation for all subsequent compression performance calculations, as it directly correlates to the expected bit lengths that would be assigned to each sourceblock in a Huffman-encoded codebook.

For data with Markovian distribution, which is common in many real-world data types including text, multimedia, and sensor data, method 2700 proceeds to a statistical analysis step 2730 where it calculates the average probability Q as the sum of squared probabilities. This can be expressed mathematically as:

$$Q = {\sum }_{i = 1}^{q} {P ( i )}^{2}$$

or equivalently as:

$$Q = \frac{{\sum }_{i = 1}^{q} {O ( i )}^{2}}{{TO}^{2}}$$

The Q value serves as a metric for estimating the entropy of the data distribution and, consequently, the achievable compression ratio. Higher Q values indicate more skewed probability distributions with greater potential for compression, while lower Q values indicate more uniform distributions with less compression potential.

Based on the calculated Q value, in a performance calculation step 2740, the method 3100 determines the compaction factor K. This formula directly relates the statistical properties of the data (represented by Q) to the expected compression performance, where smaller K values indicate better performance. The divisor (n*8) normalizes the result to account for the sourceblock length in bits. In an optimization step 2750, the method calculates K for different values of n to identify the optimal sourceblock length without generating a single codebook, dramatically reducing the computational resources required for this optimization. This approach enables a real-time tracking step 2760 of potential compression performance as new data arrives, allows quick comparison of different potential sourceblock configurations, and can be calculated using simple integer operations (additions, bit shifts) even in highly resource-constrained environments. In a decision step 2770, the system determines whether the calculated performance meets predetermined thresholds for issuing a new codebook at step 2780. The method 2700 fundamentally transforms the codebook optimization process by enabling accurate performance prediction prior to codebook generation, significantly improving the efficiency and applicability of entropy-based data compression techniques.

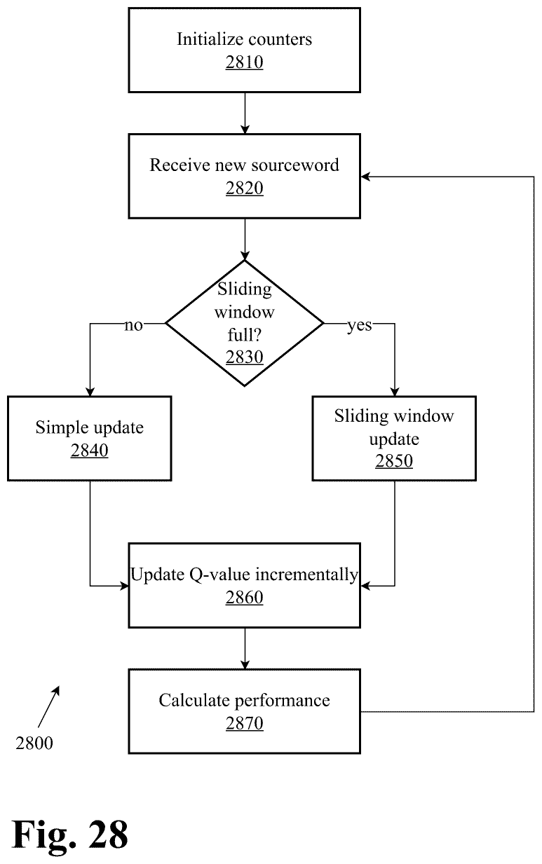

FIG. 28 is a flow diagram illustrating an exemplary method 2800 for tracking in real-time the compression performance of codebooks to be issued as the sampling window moves without issuing a single codebook, according to an embodiment. The method represents a significant advancement over traditional approaches by enabling continuous, computationally-efficient monitoring of potential codebook performance as new data arrives. This approach eliminates the need to generate test codebooks for performance evaluation, substantially reducing computational requirements while maintaining accurate performance estimates.

According to the embodiment, method 2800 begins with an initialization step 2810 where

the system establishes baseline counters and values necessary for tracking compression performance. These include setting the total occurrence counter TO to zero, initializing the sum of squared probabilities Q to zero, and setting all individual sourceblock occurrence counters O(i) to zero. This initialization provides the foundation for the incremental tracking process that follows, enabling accurate calculations without requiring storage of complete historical data.

Following initialization, the system enters a continuous tracking loop that begins with a sourceblock reception step 2820, where a new sourceblock x is received from the input data stream. This sourceblock may be of any predefined length n bytes, with the specific length determined based on application requirements or prior optimization. As each new sourceblock arrives, it is processed according to the sliding window methodology that enables real-time performance tracking with minimal computational overhead.

The process continues to a window state evaluation step 2830, where the system determines whether the sliding sampling window is full. This decision affects how the sourceblock occurrences and associated statistics are updated. If the window is not yet full (typically during system startup or after a reset), the process proceeds to a simple update step 2840. In this step, the occurrence counter O(x) for the newly received sourceblock x is incremented by one, and the total occurrence counter TO is similarly incremented. This straightforward update process continues until the sampling window reaches its predetermined capacity.

If the sampling window is already full, the process instead proceeds to a sliding window

update step 2850. In this step, the system identifies the oldest sourceblock y in the window and prepares to remove it as the window slides forward to incorporate the new sourceblock x. This sliding window approach maintains a fixed-size recent history of sourceblocks, enabling the system to adapt to changing data patterns over time while keeping memory requirements constant regardless of the total quantity of data processed.

Following either update path, the process converges at a Q-value update step 2860, where the system incrementally updates the sum of squared probabilities Q. The systems and processes described herein can be configured to leverage the incremental calculation approach, which updates Q based only on the changes to sourceblock occurrences rather than recalculating the entire sum. When the oldest sourceblock y is different from the new sourceblock x (i.e., when x does not equal y), Q is updated according to the formula:

$$x \neq y : {Q}_{next} = Q + \frac{2 * ( O ( x ) - O ( y ) + 1 )}{{TO}^{2}}$$

where O(x) and O(y) represent the occurrence counts before they are updated. If x equals y (the same sourceblock is both entering and leaving the window), then Q remains unchanged (i.e., Qₙₑₓₜ=Q). After this calculation, the occurrence counters O(x) and O(y) are updated appropriately, with O(x) incremented and O(y) decremented if applicable. This incremental approach dramatically reduces the computational cost of maintaining accurate statistics as the window slides.

The method 2800 then proceeds to a performance calculation step 2870, where the compaction factor K is calculated. This calculation provides a continuously updated estimate of the compression performance that would be achieved if a codebook were generated based on the current data distribution, without requiring actual codebook generation.

The process then returns to step 2820 to continue processing the data stream, creating a continuous feedback loop that enables real-time tracking of compression performance as data patterns evolve. This continuous tracking capability allows the system to identify optimal times for codebook updates based on performance trends, rather than arbitrary time intervals or data volume thresholds.

The method 2800 provides several significant advantages over traditional approaches. By using only integer operations (additions, subtractions, and bit shifts), it can be implemented efficiently even on highly resource-constrained devices. The incremental update approach eliminates the need to recalculate statistics from scratch as new data arrives, dramatically reducing computational requirements. Most importantly, the ability to track compression performance without generating test codebooks enables continuous optimization with minimal overhead, making efficient data compression feasible even in environments with strict resource limitations.

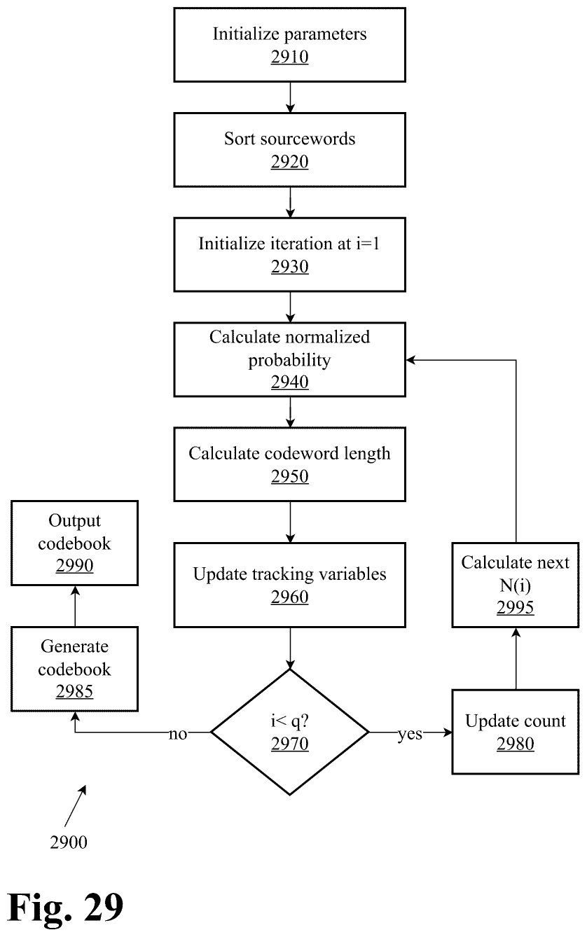

FIG. 29 is a flow diagram illustrating an exemplary method 2900 for generating a full binary tree codebook for encoding data within one bit of the optimal expected word length, according to an embodiment. The method represents a modification of the Shannon-Fano source coding algorithm that ensures the generation of a full binary tree while maintaining near-optimal compression performance. This approach achieves a balance between computational efficiency and compression ratio, making it particularly well-suited for resource-constrained environments where traditional Huffman coding would be prohibitively expensive in terms of memory and processing requirements.

According to the embodiment, the process begins with an initialization step 2910 that establishes the baseline parameters needed for the codebook generation process. In this step, the system identifies key values including q, the total number of sourceblocks collected; O(j), the number of occurrences measured for each sourceblock j, if a symbol is to be included for encoding but has no measured occurrence then O(j) may be set equal to the value of 1; and TO, the total number of occurrences measured across all sourceblocks. Additionally, several tracking variables are initialized: C(0), representing the sum of the probabilities of codewords produced, is set to 0; R(0), representing the sum of the probability of the remaining sourceblocks, is set to 1; and N(1), the normalization factor for the first sourceblock, is set to 1. These initializations establish the foundation for the iterative probability normalization process that follows.

Following initialization, the system proceeds to a sourceblock sorting step 2920, where sourceblocks are arranged in order of decreasing probability. For each sourceblock j, the probability P(j) is calculated as O(j)/TO, the ratio of its occurrences to the total occurrences. This sorting step is critical to the efficiency of the algorithm, as it ensures that more frequent sourceblocks receive shorter codewords, following the fundamental principle of entropy coding that minimizes the expected codeword length across the entire dataset.

The system then enters the main iteration loop, beginning with an iteration initialization step 2930 where the iteration counter i is set to 1. This counter tracks progress through the sorted sourceblocks, with each iteration assigning a codeword length to the next sourceblock in the sequence. The iteration-based approach allows for the incremental construction of the codebook, with each sourceblock's codeword length dependent on the processing of previous sourceblocks.

For each sourceblock, the system performs a normalized probability calculation step 2940 that determines P(j,i), the normalized probability of sourceblock j after i−1 codewords have been produced. This normalization is calculated as P(j,i)=P(j)*N(i), where N(i) is the normalization factor for iteration i. Initially, N(1)=1, so the first sourceblock's normalized probability equals its original probability. For subsequent sourceblocks, the normalization factor adjusts the probability to account for the redistribution of “lost” probability from previously processed sourceblocks, ensuring that the full probability space remains utilized throughout the process.

The system then proceeds to a codeword length calculation step 2950, where the length m(i) of the codeword for the current sourceblock is determined. This length is calculated as:

$$m ( i ) = ⌈ - {log}_{2} P ( i , j ) ⌉$$

the ceiling of the negative base-2 logarithm of the normalized probability. This formula can be expanded to:

$$m ( i ) = ⌈ {log}_{2} ( R ( i - 1 ) - {log}_{2} ( 1 - C ( i - 1 ) ) - {log}_{2} P ( i ) ⌉$$

which explicitly accounts for the remaining probability space and previously assigned codewords. This calculation ensures that each sourceblock receives a codeword length that is within one bit of the information-theoretic optimal length for its probability of occurrence.

After calculating the codeword length, the system updates tracking variables in step 2960. The cumulative probability C(i) is updated to:

$$C ( i ) = {\sum }_{j = 1}^{i} \frac{1}{{2}^{m j}}$$

### Or C(0) =0 and:

$$C ( i + 1 ) = C ( i ) + \frac{1}{{2}^{m i}}$$

reflecting the portion of the probability space now occupied by assigned codewords. The remaining probability R(i) is updated to R(i)=R(i−1)−P(i), reflecting the reduction in probability space available for subsequent sourceblocks. These tracking variables are essential for maintaining the accurate normalization of probabilities throughout the iterative process. The process then reaches a completion check in step 2970, where the system determines

whether all sourceblocks have been processed (i>=q) or if more remain (i<q). If more sourceblocks remain, the system increments the iteration counter in step 2980 and returns to the normalized probability calculation step 2940 to process the next sourceblock. This iterative approach continues until all sourceblocks have been assigned appropriate codeword lengths. The system then calculates the next normalization factor in step 2995, determining:

$$N ( i + 1 ) = \frac{1 - C ( i )}{R ( i )}$$

This normalization factor ensures that the sum of probabilities for all remaining sourceblocks, after normalization, equals the remaining probability space (1−C(i)). This adjustment is important to the generation of a full binary tree, as it redistributes the “lost” probability from previously assigned codewords (which are always rounded to powers of ½) to the remaining sourceblocks.

Once all sourceblocks have been processed, the system proceeds to codebook generation step 2985, where the full binary tree codebook is constructed based on the calculated codeword lengths. The codebook can be represented in canonical form, where only the length of each codeword needs to be stored, significantly reducing the memory requirements for the codebook. The canonical representation assigns actual codewords in lexicographic order based solely on their lengths, eliminating the need to store the bit patterns of each codeword.

At a next step, the method concludes with a return step 2990 that outputs the completed optimized codebook for use in data encoding. The resulting codebook represents a full binary tree, ensuring that every bit pattern of a given length is a valid codeword, which simplifies the encoding and decoding processes. Despite the simplifications introduced to achieve computational efficiency, the method produces codewords whose lengths are always within one bit of the information-theoretic optimal length, resulting in compression performance comparable to traditional Huffman coding but with significantly reduced computational requirements.

The method 2900 is particularly valuable for resource-constrained environments where traditional Huffman coding would be impractical due to memory or processing limitations. By requiring only four integer registers in addition to the sourceblock occurrence counters, the algorithm can be implemented efficiently on low-power devices such as IoT sensors, wearables, and embedded systems. The resulting full binary tree codebook provides near-optimal compression while enabling fast, efficient encoding and decoding, making it ideal for applications where both data efficiency and processing speed are critical considerations.

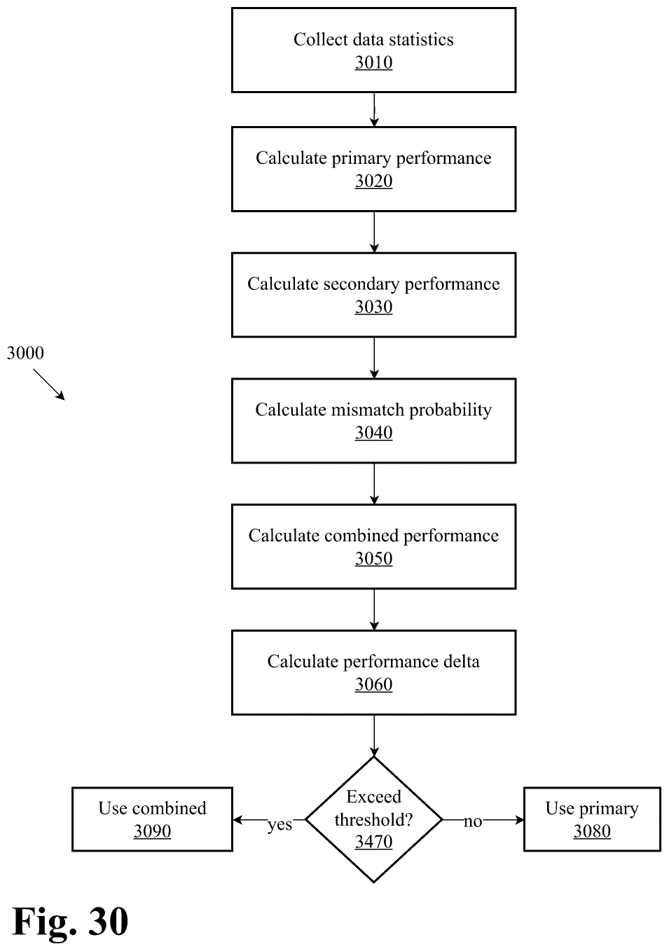

FIG. 30 is a flow diagram illustrating an exemplary method 3000 for determining when a

secondary codebook should be used in conjunction with a primary codebook to optimize compression performance, according to an embodiment. The method provides a systematic approach to evaluating whether a hybrid codebook strategy would yield sufficient performance benefits to justify the additional computational overhead. This determination is particularly valuable in resource-constrained environments where the trade-off between compression efficiency and processing requirements must be carefully balanced.

According to the embodiment, the process begins with a data statistics collection step 3010 in which the system gathers essential statistical information about the data stream being processed. During this step, the system can track sourceblock occurrences across the data stream, maintaining counters for each unique sourceblock encountered, and calculate the probability distribution of these sourceblocks. This statistical foundation is useful for accurately predicting the compression performance of different codebook configurations without the need to generate actual codebooks for testing.

Following the collection of data statistics, the method proceeds to a primary performance calculation step 3020, where the system computes the compaction factor Kₚᵣᵢₘ for an n-byte primary codebook. This calculation uses the formula K=−log₂(Q₁)/(n*8), where Q₁ represents the sum of squared probabilities for the sourceblocks that would be included in the primary codebook, n is the sourceblock length in bytes, and the multiplier 8 converts bytes to bits. The primary codebook typically uses longer sourceblocks (e.g., 8-16 bytes) to capture recurring patterns in the data, potentially achieving higher compression ratios for data with strong patterns.

The system then performs a secondary performance calculation step 3030 to compute the compaction factor K_{2nd} for a secondary codebook, which typically uses shorter sourceblocks (e.g., 1-2 bytes). The secondary codebook serves as a fallback for encoding sourceblocks that are not found in the primary codebook. This calculation follows the same principle as the primary codebook, using the formula Kₚᵣᵢₘ=−log₂(Q₂)/(m*8), where m is the shorter sourceblock length of the secondary codebook. The secondary codebook generally achieves less compression than the primary codebook but provides a more efficient encoding than raw data for sourceblocks not present in the primary codebook.

In a mismatch probability calculation step 3040, the system estimates Pₘᵢₛ, the probability that a sourceblock encountered during encoding will not be found in the primary codebook. This probability is useful for determining the expected frequency with which the system would need to fall back to the secondary codebook during actual encoding operations. Pₘᵢₛ can be calculated based on historical data patterns or estimated as the sum of probabilities for sourceblocks that would be excluded from the primary codebook due to size constraints or infrequent occurrence.

The method proceeds to a combined performance calculation step 3050, where the system computes K_{comb}. the expected compaction factor when using both primary and secondary codebooks in a hybrid approach.

In a performance delta calculation step 3060, the system determines ΔK, the absolute difference between the primary-only compaction factor Kₚᵣᵢₘ and the combined compaction factor K_{comb}. This delta represents the potential improvement (or degradation) in compression performance that would result from implementing the hybrid codebook approach compared to using only the primary codebook.

The method comprises a threshold evaluation step 3400, where the system compares the performance delta ΔK against a predetermined threshold τ. This threshold may be based on application requirements, resource constraints, and/or the acceptable trade-off between compression performance and computational overhead. If ΔK exceeds τ (indicating that the combined approach offers sufficient improvement), the system proceeds to a combined codebook usage step 3090, implementing the hybrid approach with both primary and secondary codebooks. If ΔK does not exceed τ (indicating insufficient improvement to justify the additional complexity), the system proceeds to a primary-only usage step 3080, implementing only the primary codebook for encoding.

The threshold τ plays a critical role in balancing compression efficiency with computational overhead. A higher threshold value results in less frequent use of the secondary codebook, reducing computational demands but potentially sacrificing some compression efficiency. Conversely, a lower threshold leads to more frequent use of the secondary codebook, potentially improving compression ratios at the cost of increased processing requirements. The optimal threshold value may vary based on application-specific factors such as data characteristics, available processing resources, and performance requirements.

For implementation in resource-constrained environments, the calculations in method 3000 can be performed using only integer operations, including additions, subtractions, and bit shifts, eliminating the need for floating-point arithmetic. This allows the method to be efficiently implemented on devices with limited computational capabilities, such as IoT sensors, wearables, and embedded systems.

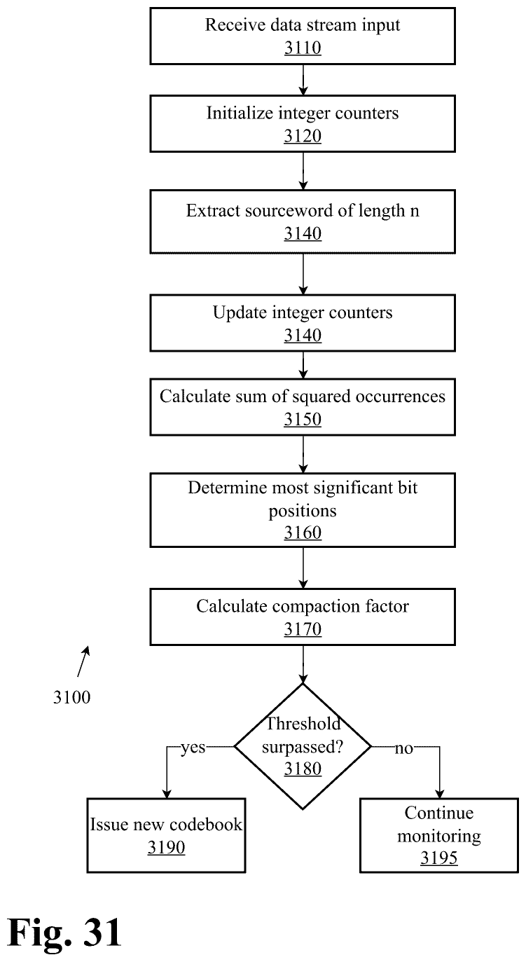

FIG. 31 is a flow diagram illustrating an exemplary method 3100 for determining compression performance of codebooks using integer-only calculations in resource-constrained computing environments, according to an embodiment. The method 3100 represents an advancement for implementing compression optimization on ultra-low-power hardware platforms such as microcontrollers without floating-point units, making the technology viable for wearables, sensors, and other extremely low-powered devices. This process enables accurate prediction of compression performance without codebook generation while using only simple integer operations, thereby dramatically reducing computational requirements for resource-constrained environments.

According to the embodiment, the process begins with a data collection step 3110 where sourceblocks of a predetermined length are collected from an input data stream. During this initialization phase, integer counters are established to track occurrences of sourceblocks, with the length of sourceblocks typically constrained to powers of 2 (such as 1, 2, 4, 8, or 16 bytes) to facilitate bit-shift operations in subsequent calculations. In a sourceblock tracking step 3120, the system maintains integer counters O(j) for tracking occurrences of each unique sourceblock j, along with a counter TO for the total number of occurrences measured across all sourceblocks. This exclusive use of integer counters ensures that all subsequent calculations can be performed without floating-point operations.

Following the collection and tracking steps, method 3100 proceeds to an integer-only

processing phase 3130 where a sum of squared occurrences is calculated using only integer addition and multiplication operations. This calculation provides the foundation for estimating compression performance without requiring floating-point division. The method then continues to a bit manipulation step 3140 where most significant bit (MSB) positions are determined for both the total squared occurrences (TO²) and the sum of squared occurrence values (ΣO(i)²). This MSB analysis serves as an integer-only approximation of logarithmic operations that would otherwise require floating-point calculations. By identifying the MSB positions through bit scanning operations, the system can approximate logarithmic values with high precision while maintaining computational efficiency.

Steps 3150-3170 represent integer only processing wherein the steps may be performed using exclusively integer-only operations such as additions, subtractions, multiplications, and bit-shifts. At step 3150 the system calculates the sum of squared occurrences. At step 3160 the system determines MSB positions. In a compaction factor calculation step 3170, the method determines the compaction factor K by computing the difference between the MSB positions and normalizing by the sourceblock length. When the sourceblock length is constrained to powers of 2, this normalization can be implemented as simple bit-shift operations rather than floating-point division, further preserving the integer-only nature of the calculations. The resulting compaction factor provides an accurate estimate of the compression performance that would be achieved if a codebook were generated based on the current data distribution, without requiring the computational expense of actual codebook generation.

The method 3100 concludes with a decision step 3180 where the calculated compaction factor is compared against a predetermined threshold to determine whether a new codebook should be issued at step 3190 or to continue monitoring at step 3195. This threshold-based approach prevents unnecessary codebook regeneration when performance improvements would be marginal, further optimizing computational resources in the constrained environment. The entire method 3100 requires only four integer registers beyond the sourceblock occurrence counters, making it exceptionally well-suited for deployment on ultra-low-power microcontrollers with limited memory and processing capabilities. This implementation enables compression optimization on devices where such functionality would otherwise be impractical due to resource limitations, opening new possibilities for efficient data transmission in wearables, IoT sensors, and other constrained computing environments.

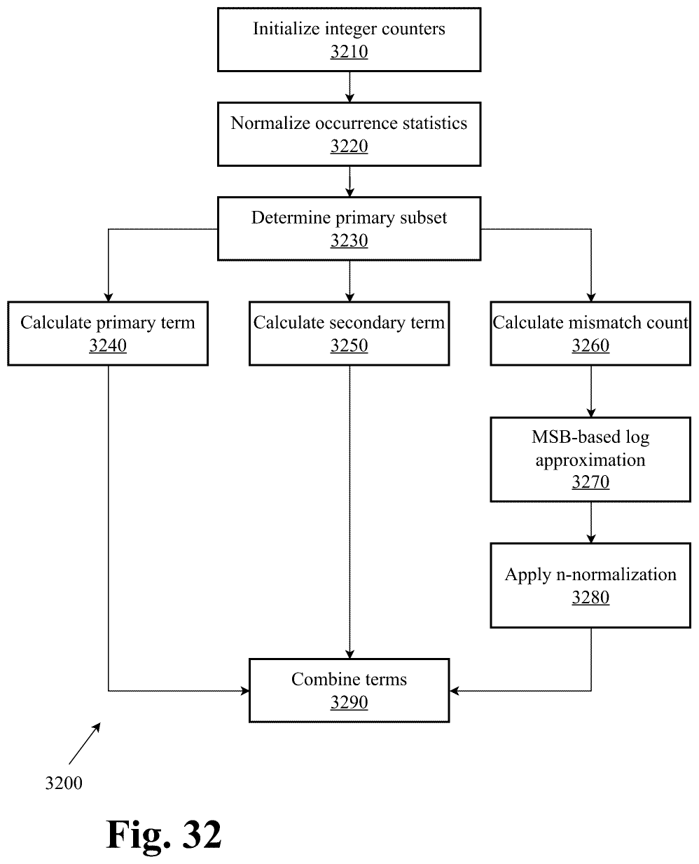

FIG. 32 is a flow diagram illustrating an exemplary method 3200 for determining the compression performance of a hybrid codebook system using only integer operations and bit manipulations, according to an embodiment. This method enables accurate performance estimation without floating-point operations, making it suitable for implementation on ultra-low-power microcontrollers and other resource-constrained devices lacking floating-point units.

According to the embodiment, the process begins with an initialization step 3210 where the system establishes integer counters for tracking sourceblock occurrences. Total occurrence counter TO and individual sourceblock occurrence counters O(j) are set up as integer values. During this step, the system also constrains sourceblock lengths to powers of two (1, 2, 4, 8, 16 bytes), which enables the replacement of division operations with more efficient bit shifts in subsequent calculations. These constraints are critical for ensuring that all operations can be performed using only integer arithmetic and bit manipulations.

Following initialization, the method proceeds to a normalization step 3220 where occurrence statistics are scaled to a fixed total value across all sourceblock lengths being evaluated. This normalization ensures that performance metrics can be consistently compared across different configurations without requiring floating-point division. By selecting a normalization factor that is a power of two, all scaling operations can be implemented using bit shifts rather than division, maintaining the integer-only nature of the approach while ensuring mathematical accuracy.

The method then performs a primary subset determination step 3230, where it identifies the q top sourceblocks to include in the primary codebook. This selection is based on integer occurrence count comparisons, sorting sourceblocks by frequency without requiring floating-point operations. The parameter q may be determined based on memory constraints or optimization goals, with larger values of q potentially improving compression efficiency at the cost of increased codebook size.

With the primary subset determined, the method performs three parallel calculation paths to determine the components of the overall performance metric. The first is a primary term calculation step 3240, where the system computes the contribution of the primary codebook to the overall performance. Instead of calculating a sum of squared probabilities as would be done in a floating-point implementation, the system works directly with squared occurrence counts. For each sourceblock in the primary subset, its occurrence count is squared using integer multiplication, and these squared values are summed to produce the primary term. This approach avoids the division operations that would normally be required to convert occurrence counts to probabilities.

Concurrently, the method performs a secondary term calculation step 3250 to determine the contribution of the secondary codebook to the overall performance. This calculation follows the same integer-based approach, working with squared occurrence counts for the 1-byte patterns that would be encoded using the secondary codebook. As with the primary term, this calculation uses only integer multiplication operations, avoiding floating-point arithmetic entirely.

The third parallel path begins with a mismatch count calculation step 3260, where the system determines the number of occurrences Oₘᵢₛ that would not be covered by the primary codebook. This is calculated as the difference between the total occurrence count TO and the sum of occurrence counts for sourceblocks in the primary subset, using only integer subtraction. This mismatch count is critical for accurately estimating the frequency with which the system would need to fall back to the secondary codebook during actual encoding operations. The method then proceeds to an MSB-based logarithm approximation step 3270 that

transforms what would normally be a logarithmic calculation into a sequence of bit manipulation operations. This step is crucial for approximating the logarithmic term required in the performance calculation without using floating-point operations. The process involves determining the positions of the most significant bits (MSBs) in both the total occurrence count (TOₘᵢₛ) and the mismatch count (Oₘᵢₛ), calculating the difference between these positions, performing right shift operations based on this difference, and comparing the results to determine whether to add one to the bit position difference (implementing the ceiling function). This approximation provides sufficient accuracy for performance estimation while requiring only bit manipulation operations.

Following the logarithm approximation, the method performs an n-normalization step 3280 where the sourceblock length factor is applied to the calculation. In floating-point implementations, this would involve division by n*8 (where n is the sourceblock length in bytes and 8 converts bytes to bits). In the integer-only implementation, this division is replaced with a right bit shift by log₂(n)+3, taking advantage of the constraint that n is always a power of two. This approach achieves the same mathematical result while avoiding division operations.

With all three components calculated, the method proceeds to a term combination step 3290 where the primary, secondary, and mismatch terms are combined using only integer addition operations. This combined value represents the overall performance metric for the hybrid codebook system with the current configuration parameters, calculated entirely using integer arithmetic and bit manipulations.

The method concludes with a return step where it outputs the combined performance metric for use in codebook optimization, configuration selection, or compression strategy determination. This metric provides a precise estimate of the compression performance that would be achieved using the hybrid codebook approach, without requiring floating-point operations or the generation of actual codebooks.

The integer-only hybrid codebook performance estimation method 3700 provides several significant advantages for resource-constrained environments. By eliminating floating-point operations entirely, it reduces both processing requirements and power consumption, making sophisticated compression optimization viable on ultra-low-power microcontrollers such as ARM Cortex-M series processors. The method maintains mathematical accuracy while dramatically reducing computational complexity, enabling advanced compression techniques in applications where both compression efficiency and energy conservation are critical requirements.

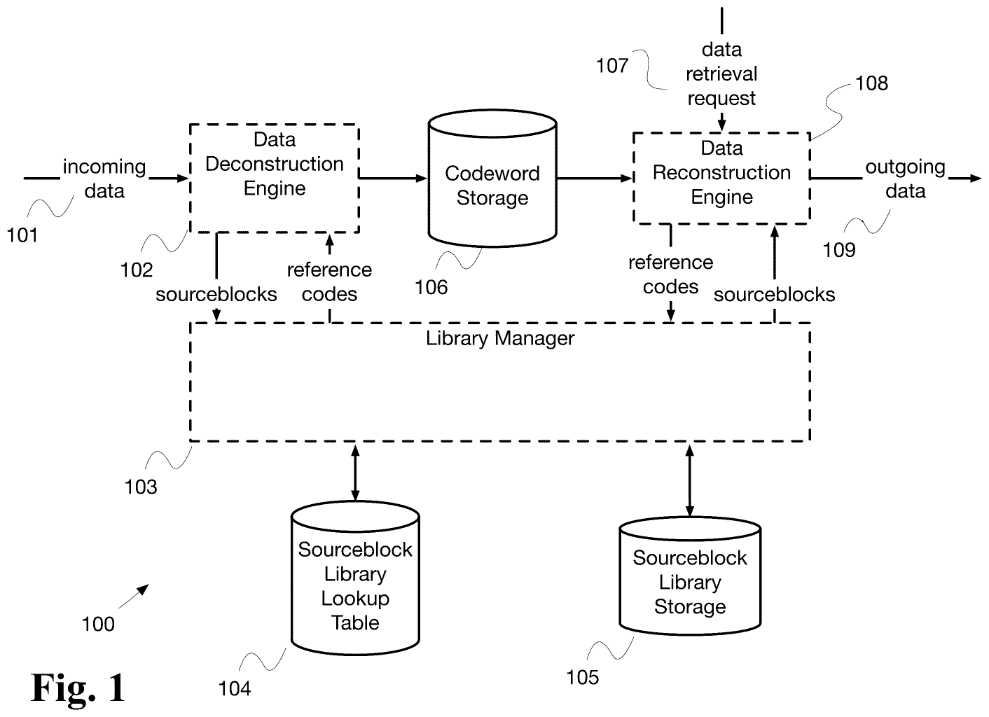

FIG. 1 is a diagram showing an embodiment 100 of the system in which all components of the system are operated locally. As incoming data 101 is received by data deconstruction engine 102. Data deconstruction engine 102 breaks the incoming data into sourceblocks, which are then sent to library manager 103. Using the information contained in sourceblock library lookup table 104 and sourceblock library storage 105, library manager 103 returns reference codes to data deconstruction engine 102 for processing into codewords, which are stored in codeword storage 106. When a data retrieval request 107 is received, data reconstruction engine 108 obtains the codewords associated with the data from codeword storage 106, and sends them to library manager 103. Library manager 103 returns the appropriate sourceblocks to data reconstruction engine 108, which assembles them into the proper order and sends out the data in its original form 109.

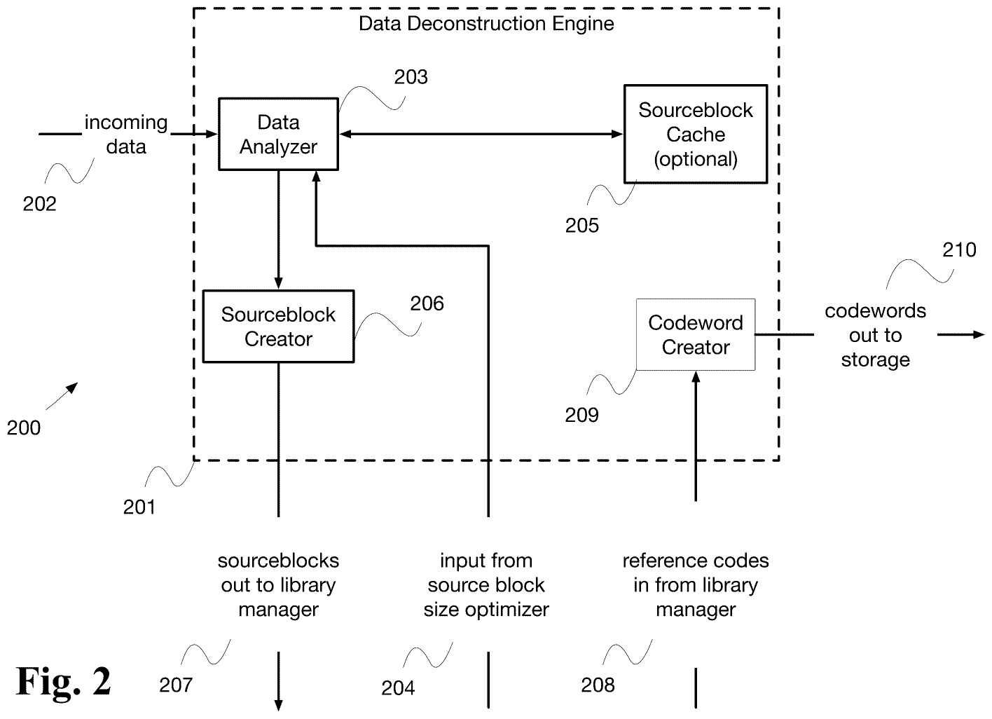

FIG. 2 is a diagram showing an embodiment of one aspect 200 of the system, specifically data deconstruction engine 201. Incoming data 202 is received by data analyzer 203, which optimally analyzes the data based on machine learning algorithms and input 204 from a sourceblock size optimizer, which is disclosed below. Data analyzer may optionally have access to a sourceblock cache 205 of recently-processed sourceblocks, which can increase the speed of the system by avoiding processing in library manager 103. Based on information from data analyzer 203, the data is broken into sourceblocks by sourceblock creator 206, which sends sourceblocks 207 to library manager 203 for additional processing. Data deconstruction engine 201 receives reference codes 208 from library manager 103, corresponding to the sourceblocks in the library that match the sourceblocks sent by sourceblock creator 206, and codeword creator 209 processes the reference codes into codewords comprising a reference code to a sourceblock and a location of that sourceblock within the data set. The original data may be discarded, and the codewords representing the data are sent out to storage 210.

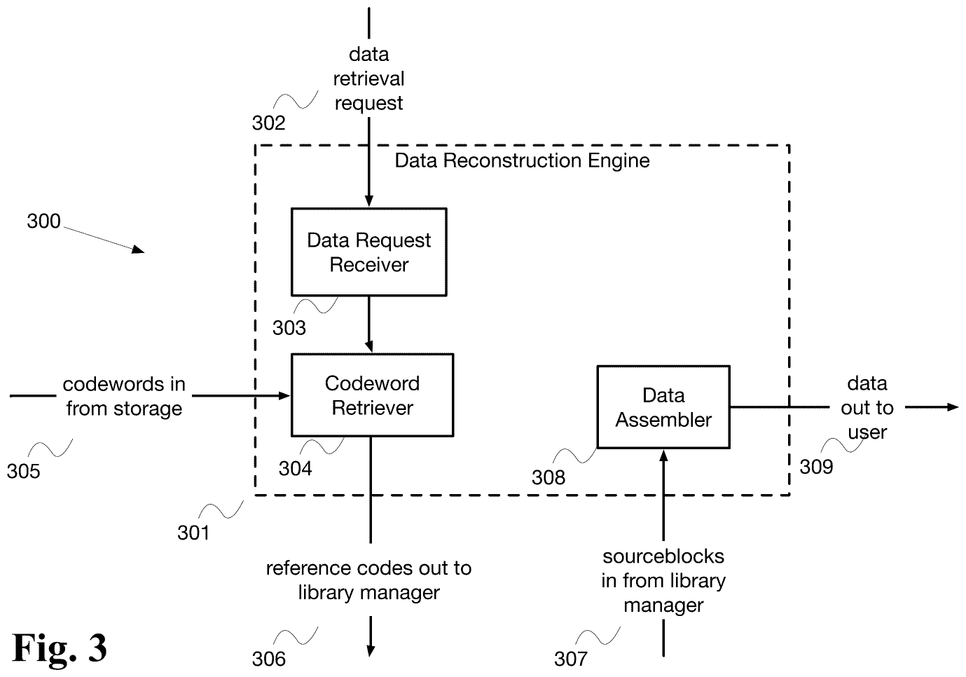

FIG. 3 is a diagram showing an embodiment of another aspect of system 300, specifically data reconstruction engine 301. When a data retrieval request 302 is received by data request receiver 303 (in the form of a plurality of codewords corresponding to a desired final data set), it passes the information to data retriever 304, which obtains the requested data 305 from storage. Data retriever 304 sends, for each codeword received, a reference codes from the codeword 306 to library manager 103 for retrieval of the specific sourceblock associated with the reference code. Data assembler 308 receives the sourceblock 307 from library manager 103 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 309 in its original form.

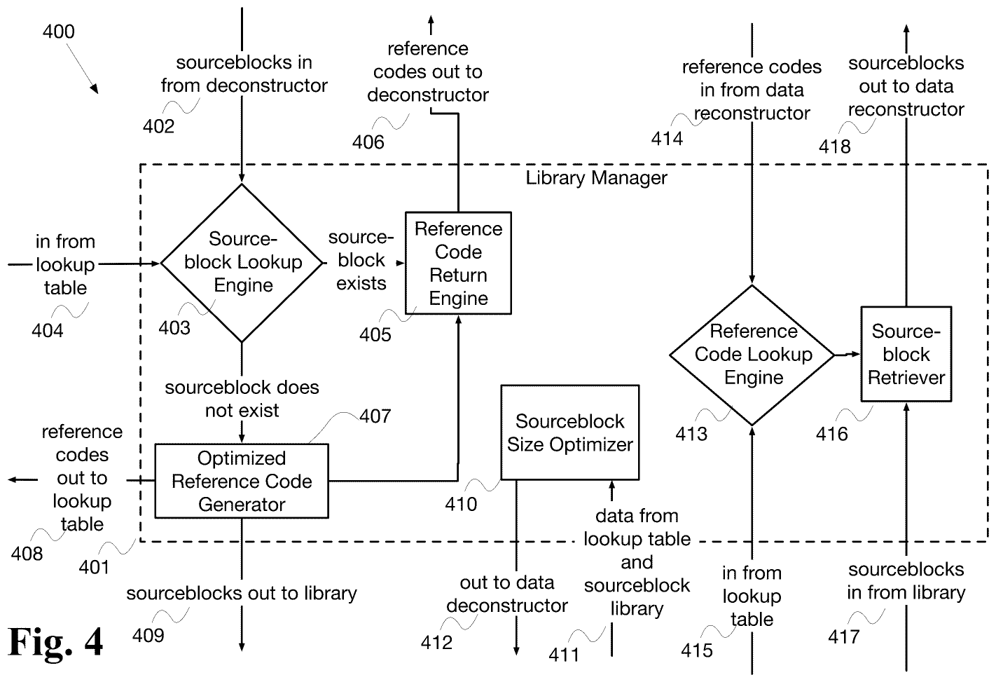

FIG. 4 is a diagram showing an embodiment of another aspect of the system 400, specifically library manager 401. One function of library manager 401 is to generate reference codes from sourceblocks received from data deconstruction engine 301. As sourceblocks are received 402 from data deconstruction engine 301, sourceblock lookup engine 403 checks sourceblock library lookup table 404 to determine whether those sourceblocks already exist in sourceblock library storage 105. If a particular sourceblock exists in sourceblock library storage 105, reference code return engine 405 sends the appropriate reference code 406 to data deconstruction engine 301. If the sourceblock does not exist in sourceblock library storage 105, optimized reference code generator 407 generates a new, optimized reference code based on machine learning algorithms. Optimized reference code generator 407 then saves the reference code 408 to sourceblock library lookup table 104; saves the associated sourceblock 409 to sourceblock library storage 105; and passes the reference code to reference code return engine 405 for sending 406 to data deconstruction engine 301. Another function of library manager 401 is to optimize the size of sourceblocks in the system. Based on information 411 contained in sourceblock library lookup table 104, sourceblock size optimizer 410 dynamically adjusts the size of sourceblocks in the system based on machine learning algorithms and outputs that information 412 to data analyzer 203. Another function of library manager 401 is to return sourceblocks associated with reference codes received from data reconstruction engine 301. As reference codes are received 414 from data reconstruction engine 301, reference code lookup engine 413 checks sourceblock library lookup table 415 to identify the associated sourceblocks; passes that information to sourceblock retriever 416, which obtains the sourceblocks 417 from sourceblock library storage 105; and passes them 418 to data reconstruction engine 301.

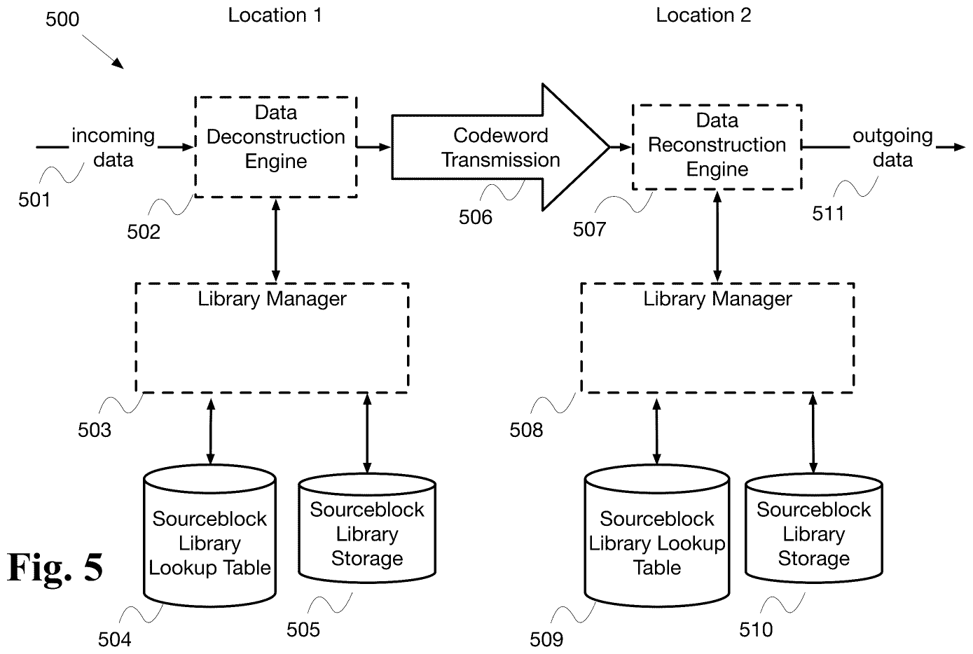

FIG. 5 is a diagram showing another embodiment of system 500, in which data is transferred between remote locations. As incoming data 501 is received by data deconstruction engine 502 at Location 1, data deconstruction engine 301 breaks the incoming data into sourceblocks, which are then sent to library manager 503 at Location 1. Using the information contained in sourceblock library lookup table 504 at Location 1 and sourceblock library storage 505 at Location 1, library manager 503 returns reference codes to data deconstruction engine 301 for processing into codewords, which are transmitted 506 to data reconstruction engine 507 at Location 2. In the case where the reference codes contained in a particular codeword have been newly generated by library manager 503 at Location 1, the codeword is transmitted along with a copy of the associated sourceblock. As data reconstruction engine 507 at Location 2 receives the codewords, it passes them to library manager module 508 at Location 2, which looks up the sourceblock in sourceblock library lookup table 509 at Location 2 and retrieves the associated from sourceblock library storage 510. Where a sourceblock has been transmitted along with a codeword, the sourceblock is stored in sourceblock library storage 510 and sourceblock library lookup table 504 is updated. Library manager 503 returns the appropriate sourceblocks to data reconstruction engine 507, which assembles them into the proper order and sends the data in its original form 511.

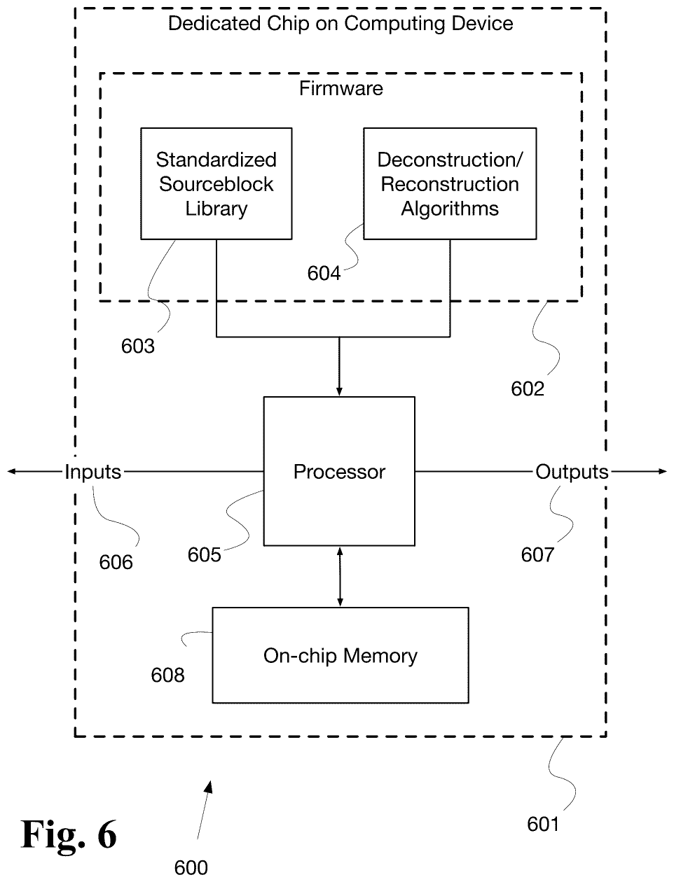

FIG. 6 is a diagram showing an embodiment 600 in which a standardized version of a

sourceblock library 603 and associated algorithms 604 would be encoded as firmware 602 on a dedicated processing chip 601 included as part of the hardware of a plurality of devices 600. Contained on dedicated chip 601 would be a firmware area 602, on which would be stored a copy of a standardized sourceblock library 603 and deconstruction/reconstruction algorithms 604 for processing the data. Processor 605 would have both inputs 606 and outputs 607 to other hardware on the device 600. Processor 605 would store incoming data for processing on on-chip memory 608, process the data using standardized sourceblock library 603 and deconstruction/reconstruction algorithms 604, and send the processed data to other hardware on device 600. Using this embodiment, the encoding and decoding of data would be handled by dedicated chip 601, keeping the burden of data processing off device's 600 primary processors.

Any device equipped with this embodiment would be able to store and transmit data in a highly optimized, bandwidth-efficient format with any other device equipped with this embodiment.

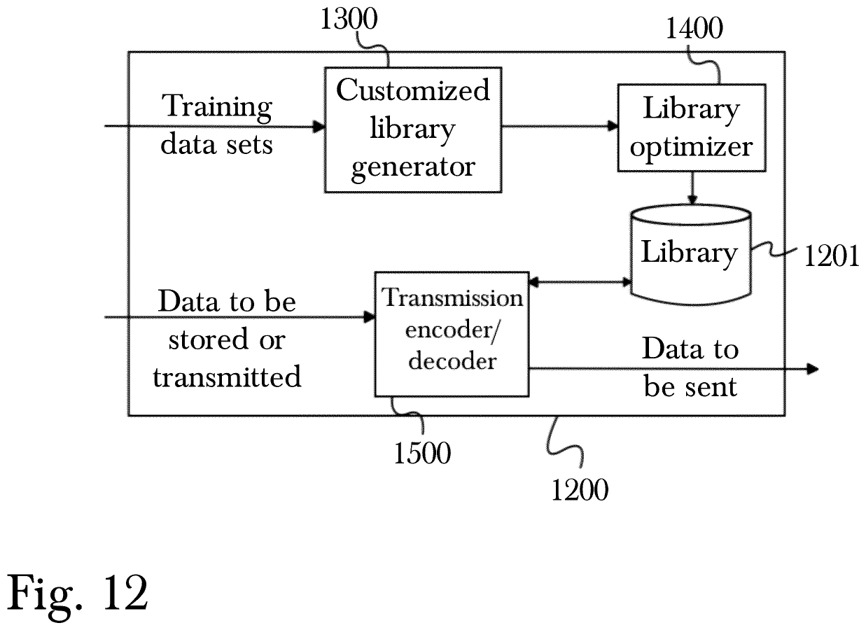

FIG. 12 is a diagram showing an exemplary system architecture 1200, according to a preferred embodiment of the invention. Incoming training data sets may be received at a customized library generator 1300 that processes training data to produce a customized word library 1201 comprising key-value pairs of data words (each comprising a string of bits) and their corresponding calculated binary Huffman codewords. The resultant word library 1201 may then be processed by a library optimizer 1400 to reduce size and improve efficiency, for example by pruning low-occurrence data entries or calculating approximate codewords that may be used to match more than one data word. A transmission encoder/decoder 1500 may be used to receive incoming data intended for storage or transmission, process the data using a word library 1201 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1200 provides near-instantaneous source coding that is dictionary-based and learned in advance from sample training data, so that encoding and decoding may happen concurrently with data transmission. This results in computational latency that is near zero but the data size reduction is comparable to classical compression. For example, if N bits are to be transmitted from sender to receiver, the compression ratio of classical compression is C, the ratio between the deflation factor of system 1200 and that of multi-pass source coding is p, the classical compression encoding rate is R_{C} bit/s and the decoding rate is R_{D} bit/s, and the transmission speed is S bit/s, the compress-send-decompress time will be

$${T}_{o l d} = \frac{N}{{R}_{C}} + \frac{N}{C S} + \frac{N}{C {R}_{D}}$$

while the transmit-while-coding time for system 1200 will be (assuming that encoding and decoding happen at least as quickly as network latency):

$${T}_{n e w} = \frac{{N}_{p}}{CS}$$

so that the total data transit time improvement factor is

$$\frac{{T}_{o l d}}{{T}_{n e w}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1 .$$

This is a reasonable scenario given that typical values in real-world practice are C=0.32, RC=1.1·10¹², R_{D}=4.2·10¹², S=10¹¹, giving

$$\frac{CS}{{R}_{C}} + \frac{S}{{R}_{D}} = 0.053 . ¨ ,$$

such that system 1200 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{tp}{CS}$$

since encoding and decoding occur concurrently with data transmission. On the other hand, the latency associated with classical compression is

$${delay}_{priorart} = \frac{N}{{R}_{C}} + \frac{N}{CS} + \frac{N}{C {R}_{D}}$$

where N is the packet/file size. Even with the generous values chosen above as well as N=512K, t=10, and p=1.05, this results in delayᵢₙᵥₑₙₜᵢₒₙ≈3.3·10⁻¹⁰ while delayₚᵣᵢₒᵣₐᵣₜ≈1.3·10^{-7,} a more than 400-fold reduction in latency.

A key factor in the efficiency of Huffman coding used by system 1200 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1200 addresses this by restriction of data types and density estimation; training data is provided that is representative of the type of data anticipated in “real-world” use of system 1200, which is then used to model the distribution of binary strings in the data in order to build a Huffman code word library 1200.

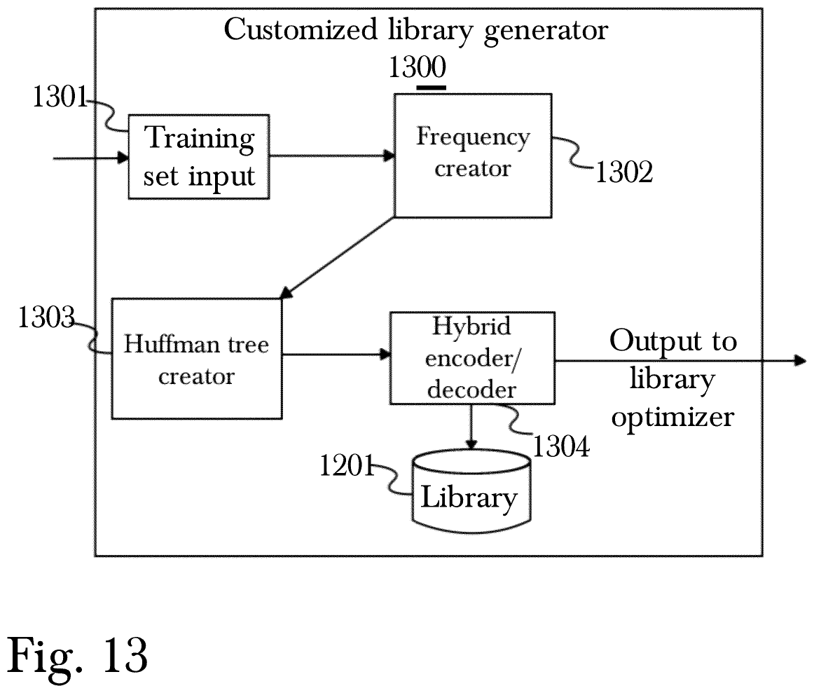

FIG. 13 is a diagram showing a more detailed architecture for a customized library generator 1300. When an incoming training data set 1301 is received, it may be analyzed using a frequency creator 1302 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yield better results when used with real-world data (rather than, for example, being only based on a single training data set that may not be very similar to a received non-training data set). A second Huffman tree creator 1303 may be utilized to identify words that do not match any existing entries in a word library 1201 and pass them to a hybrid encoder/decoder 1304, that then calculates a binary Huffman codeword for the mismatched word and adds the codeword and original data to the word library 1201 as a new key-value pair. In this manner, customized library generator 1300 may be used both to establish an initial word library 1201 from a first training set, as well as expand the word library 1201 using additional training data to improve operation.

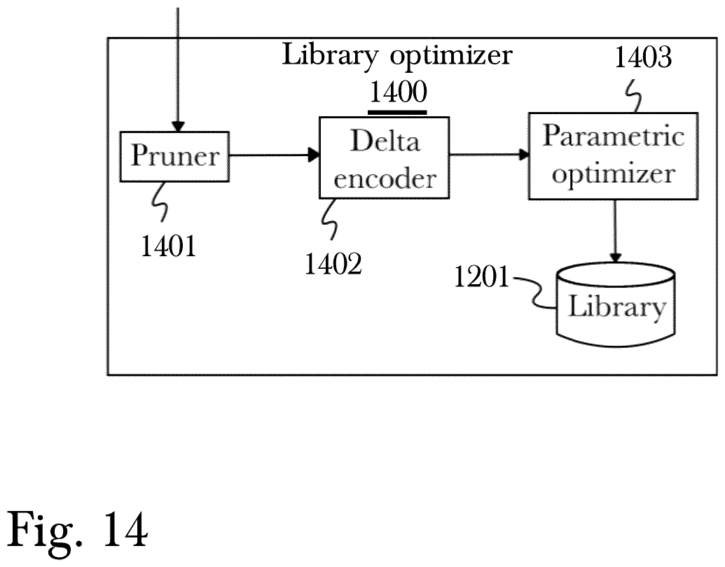

FIG. 14 is a diagram showing a more detailed architecture for a library optimizer 1400. A pruner 1401 may be used to load a word library 1201 and reduce its size for efficient operation, for example by sorting the word library 1201 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1201 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1402 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1403 may load configuration parameters for operation to optimize the use of the word library 1201 during operation. Best-practice parameter/hyperparameter optimization strategies such as stochastic gradient descent, quasi-random grid search, and evolutionary search may be used to make optimal choices for all interdependent settings playing a role in the functionality of system 1200. In cases where lossless compression is not required, the delta value may be discarded at the expense of introducing some limited errors into any decoded (reconstructed) data.

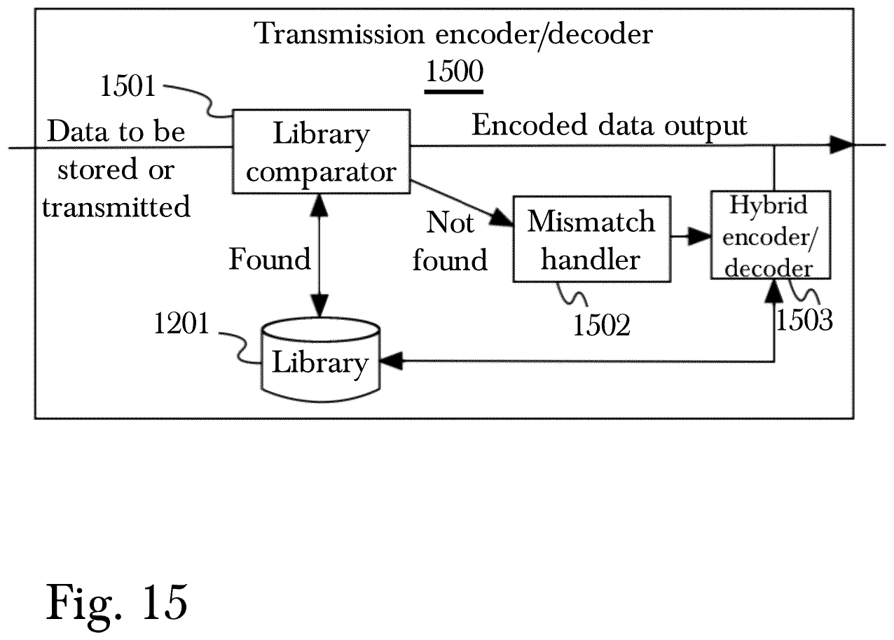

FIG. 15 is a diagram showing a more detailed architecture for a transmission encoder/decoder 1500. According to various arrangements, transmission encoder/decoder 1500 may be used to deconstruct data for storage or transmission, or to reconstruct data that has been received, using a word library 1201. A library comparator 1501 may be used to receive data comprising words or codewords and compare against a word library 1201 by dividing the incoming stream into substrings of length t and using a fast hash to check word library 1201 for each substring. If a substring is found in word library 1201, the corresponding key/value (that is, the corresponding source word or codeword, according to whether the substring used in comparison was itself a word or codeword) is returned and appended to an output stream. If a given substring is not found in word library 1201, a mismatch handler 1502 and hybrid encoder/decoder 1503 may be used to handle the mismatch similarly to operation during the construction or expansion of word library 1201. A mismatch handler 1502 may be utilized to identify words that do not match any existing entries in a word library 1201 and pass them to a hybrid encoder/decoder 1503, that then calculates a binary Huffman codeword using shorter block-length encoding for the mismatched word and adds the codeword and original data to the word library 1201 as a new key-value pair. The newly-produced codeword may then be appended to the output stream. In arrangements where a mismatch indicator is included in a received data stream, this may be used to preemptively identify a substring that is not in word library 1201 (for example, if it was identified as a mismatch on the transmission end), and handled accordingly without the need for a library lookup.

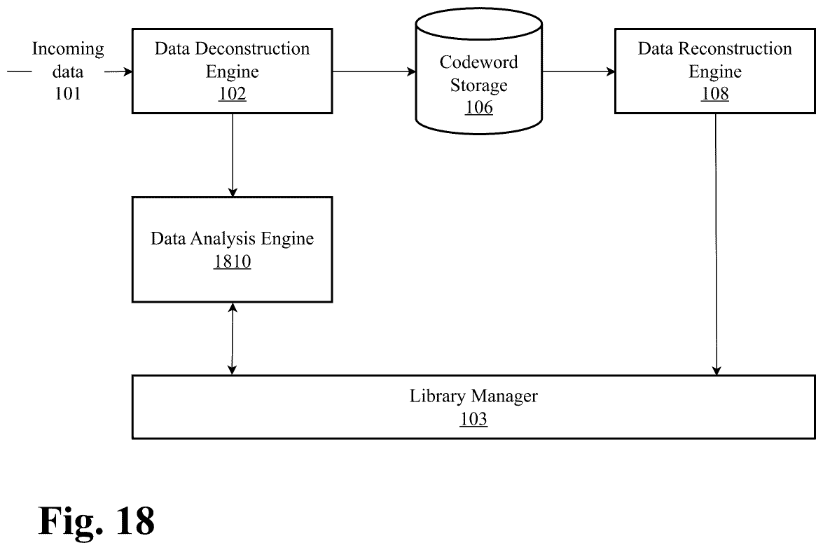

FIG. 18 is an exemplary system architecture of a data encoding system used for data mining and analysis purposes. Much like in FIG. 1, incoming data 101 to be deconstructed is sent to a data deconstruction engine 102, which may attempt to deconstruct the data and turn it into a collection of codewords using a library manager 103. Codeword storage 106 serves to store unique codewords from this process and may be queried by a data reconstruction engine 108 which may reconstruct the original data from the codewords, using a library manager 103. A data analysis engine 1810, typically operating while the system is otherwise idle, sends requests for data to the data reconstruction engine 108, which retrieves the codewords representing the requested data from codeword storage 106, reconstructs them into the data represented by the codewords, and send the reconstructed data to the data analysis engine 1810 for analysis and extraction of useful data (i.e., data mining). Because the speed of reconstruction is significantly faster than decompression using traditional compression technologies (i.e., significantly less decompression latency), this approach makes data mining feasible. Very often, data stored using traditional compression is not mined precisely because decompression lag makes it unfeasible, especially during shorter periods of system idleness. Increasing the speed of data reconstruction broadens the circumstances under which data mining of stored data is feasible.

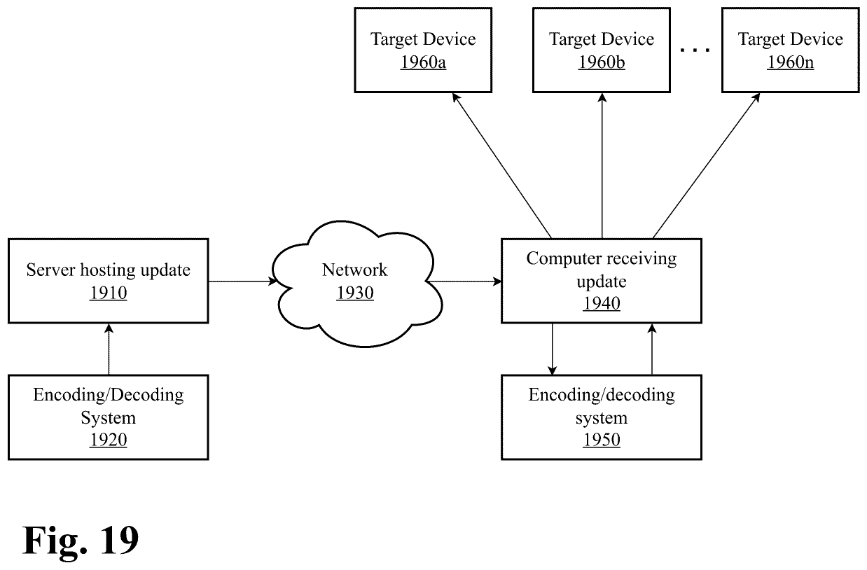

FIG. 19 is an exemplary system architecture of a data encoding system used for remote software and firmware updates. Software and firmware updates typically require smaller, but more frequent, file transfers. A server which hosts a software or firmware update 1910 may host an encoding-decoding system 1920, allowing for data to be encoded into, and decoded from, sourceblocks or codewords, as disclosed in previous figures. Such a server may possess a software update, operating system update, firmware update, device driver update, or any other form of software update, which in some cases may be minor changes to a file, but nevertheless necessitate sending the new, completed file to the recipient. Such a server is connected over a network 1930, which is further connected to a recipient computer 1940, which may be connected to a server 1910 for receiving such an update to its system. In this instance, the recipient device 1940 also hosts the encoding and decoding system 1950, along with a codebook or library of reference codes that the hosting server 1910 also shares. The updates are retrieved from storage at the hosting server 1910 in the form of codewords, transferred over the network 1930 in the form of codewords, and reconstructed on the receiving computer 1940. In this way, a far smaller file size, and smaller total update size, may be sent over a network. The receiving computer 1940 may then install the updates on any number of target computing devices 1960a-n, using a local network or other high-bandwidth connection.

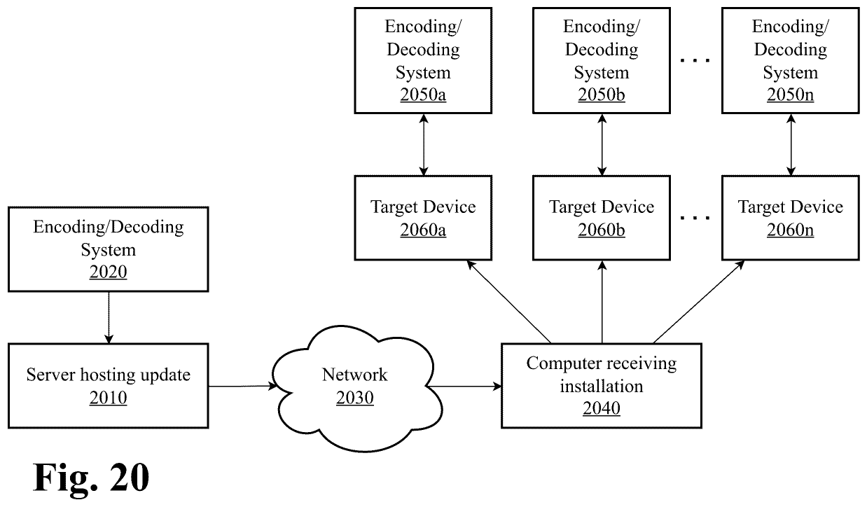

FIG. 20 is an exemplary system architecture of a data encoding system used for large-scale software installation such as operating systems. Large-scale software installations typically require very large, but infrequent, file transfers. A server which hosts an installable software 2010 may host an encoding-decoding system 2020, allowing for data to be encoded into, and decoded from, sourceblocks or codewords, as disclosed in previous figures. The files for the large scale software installation are hosted on the server 2010, which is connected over a network 2030 to a recipient computer 2040. In this instance, the encoding and decoding system 2050a-n is stored on or connected to one or more target devices 2060a-n, along with a codebook or library of reference codes that the hosting server 2010 shares. The software is retrieved from storage at the hosting server 2010 in the form of codewords and transferred over the network 2030 in the form of codewords to the receiving computer 2040. However, instead of being reconstructed at the receiving computer 2040, the codewords are transmitted to one or more target computing devices, and reconstructed and installed directly on the target devices 2060a-n. In this way, a far smaller file size, and smaller total update size, may be sent over a network or transferred between computing devices, even where the network 2030 between the receiving computer 2040 and target devices 2060a-n is low bandwidth, or where there are many target devices 2060a-n.

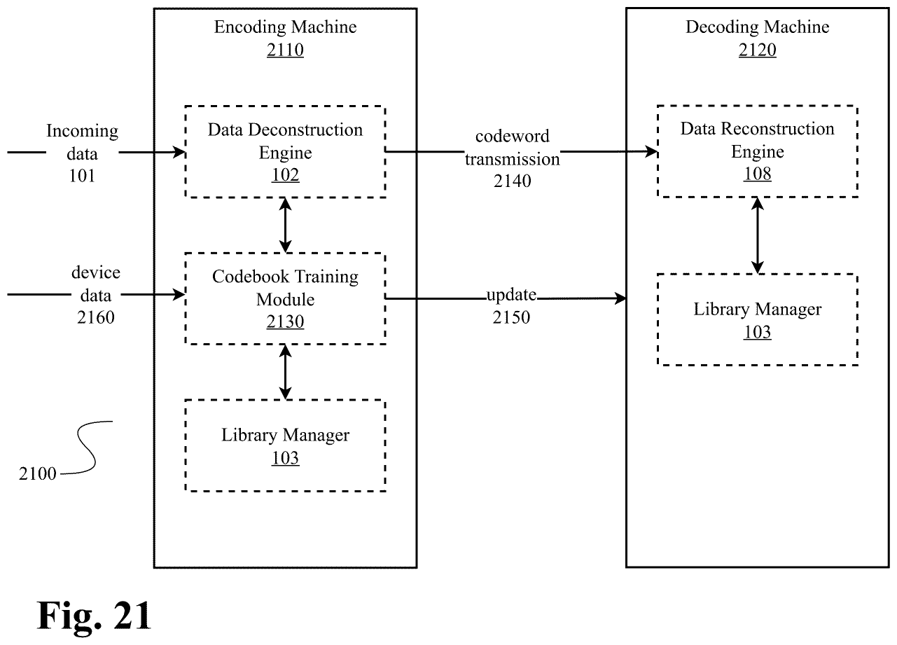

FIG. 21 is a block diagram of an exemplary system architecture 2100 of a codebook

training system for a data encoding system, according to an embodiment. According to this embodiment, two separate machines may be used for encoding 2110 and decoding 2120. Much like in FIG. 1, incoming data 101 to be deconstructed is sent to a data deconstruction engine 102 residing on encoding machine 2110, which may attempt to deconstruct the data and turn it into a collection of codewords using a library manager 103. Codewords may be transmitted 2140 to a data reconstruction engine 108 residing on decoding machine 2120, which may reconstruct the original data from the codewords, using a library manager 103. However, according to this embodiment, a codebook training module 2130 is present on the decoding machine 2110, communicating in-between a library manager 103 and a deconstruction engine 102. According to other embodiments, codebook training module 2130 may reside instead on decoding machine 2120 if the machine has enough computing resources available; which machine the module 2130 is located on may depend on the system user's architecture and network structure. Codebook training module 2130 may send requests for data to the data reconstruction engine 2110, which routes incoming data 101 to codebook training module 2130. Codebook training module 2130 may perform analyses on the requested data in order to gather information about the distribution of incoming data 101 as well as monitor the encoding/decoding model performance. Additionally, codebook training module 2130 may also request and receive device data 2160 to supervise network connected devices and their processes and, according to some embodiments, to allocate training resources when requested by devices running the encoding system. Devices may include, but are not limited to, encoding and decoding machines, training machines, sensors, mobile computer devices, and Internet-of-things (“IoT”) devices. Based on the results of the analyses, the codebook training module 2130 may create a new training dataset from a subset of the requested data in order to counteract the effects of data drift on the encoding/decoding models, and then publish updated 2150 codebooks to both the encoding machine 2110 and decoding machine 2120.

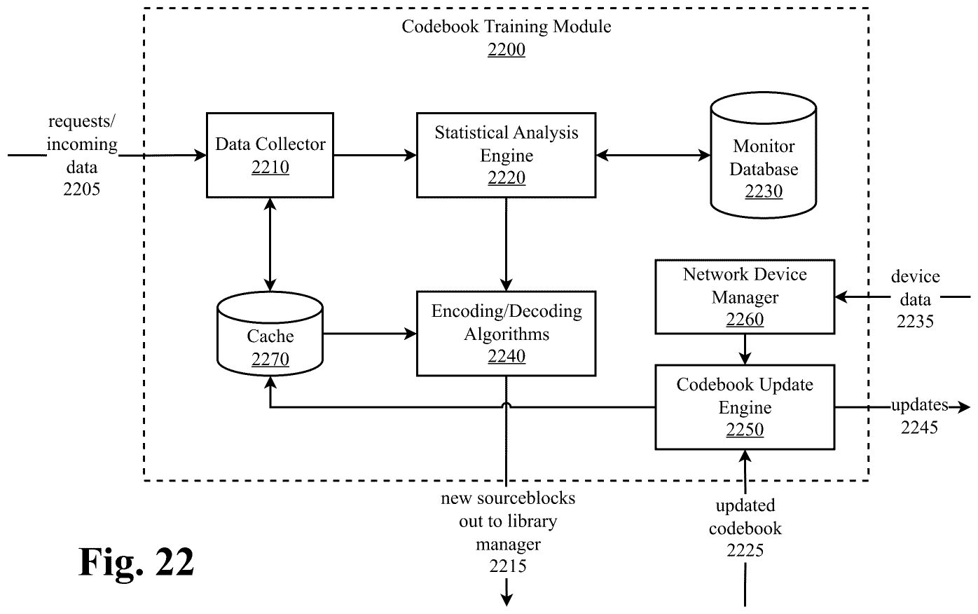

FIG. 22 is a block diagram of an exemplary architecture for a codebook training module 2200, according to an embodiment. According to the embodiment, a data collector 2210 is present which may send requests for incoming data 2205 to a data deconstruction engine 102 which may receive the request and route incoming data to codebook training module 2200 where it may be received by data collector 2210. Data collector 2210 may be configured to request data periodically such as at schedule time intervals, or for example, it may be configured to request data after a certain amount of data has been processed through the encoding machine 2110 or decoding machine 2120. The received data may be a plurality of sourceblocks, which are a series of binary digits, originating from a source packet otherwise referred to as a datagram. The received data may compiled into a test dataset and temporarily stored in a cache 2270. Once stored, the test dataset may be forwarded to a statistical analysis engine 2220 which may utilize one or more algorithms to determine the probability distribution of the test dataset. Best-practice probability distribution algorithms such as Kullback-Leibler divergence, adaptive windowing, and Jensen-Shannon divergence may be used to compute the probability distribution of training and test datasets. A monitoring database 2230 may be used to store a variety of statistical data related to training datasets and model performance metrics in one place to facilitate quick and accurate system monitoring capabilities as well as assist in system debugging functions. For example, the original or current training dataset and the calculated probability distribution of this training dataset used to develop the current encoding and decoding algorithms may be stored in monitor database 2230.

Since data drifts involve statistical change in the data, the best approach to detect drift is

by monitoring the incoming data's statistical properties, the model's predictions, and their correlation with other factors. After statistical analysis engine 2220 calculates the probability distribution of the test dataset it may retrieve from monitor database 2230 the calculated and stored probability distribution of the current training dataset. It may then compare the two probability distributions of the two different datasets in order to verify if the difference in calculated distributions exceeds a predetermined difference threshold. If the difference in distributions does not exceed the difference threshold, that indicates the test dataset, and therefore the incoming data, has not experienced enough data drift to cause the encoding/decoding system performance to degrade significantly, which indicates that no updates are necessary to the existing codebooks. However, if the difference threshold has been surpassed, then the data drift is significant enough to cause the encoding/decoding system performance to degrade to the point where the existing models and accompanying codebooks need to be updated. According to an embodiment, an alert may be generated by statistical analysis engine 2220 if the difference threshold is surpassed or if otherwise unexpected behavior arises.

In the event that an update is required, the test dataset stored in the cache 2270 and its associated calculated probability distribution may be sent to monitor database 2230 for long term storage. This test dataset may be used as a new training dataset to retrain the encoding and decoding algorithms 2240 used to create new sourceblocks based upon the changed probability distribution. The new sourceblocks may be sent out to a library manager 2215 where the sourceblocks can be assigned new codewords. Each new sourceblock and its associated codeword may then be added to a new codebook and stored in a storage device. The new and updated codebook may then be sent back 2225 to codebook training module 2200 and received by a codebook update engine 2250. Codebook update engine 2250 may temporarily store the received updated codebook in the cache 2270 until other network devices and machines are ready, at which point codebook update engine 2250 will publish the updated codebooks 2245 to the necessary network devices.

A network device manager 2260 may also be present which may request and receive network device data 2235 from a plurality of network connected devices and machines. When the disclosed encoding system and codebook training system 2100 are deployed in a production environment, upstream process changes may lead to data drift, or other unexpected behavior. For example, a sensor being replaced that changes the units of measurement from inches to centimeters, data quality issues such as a broken sensor always reading zero, and covariate shift which occurs when there is a change in the distribution of input variables from the training set. These sorts of behavior and issues may be determined from the received device data 2235 in order to identify potential causes of system error that is not related to data drift and therefore does not require an updated codebook. This can save network resources from being unnecessarily used on training new algorithms as well as alert system users to malfunctions and unexpected behavior devices connected to their networks. Network device manager 2260 may also utilize device data 2235 to determine available network resources and device downtime or periods of time when device usage is at its lowest. Codebook update engine 2250 may request network and device availability data from network device manager 2260 in order to determine the most optimal time to transmit updated codebooks (i.e., trained libraries) to encoder and decoder devices and machines.

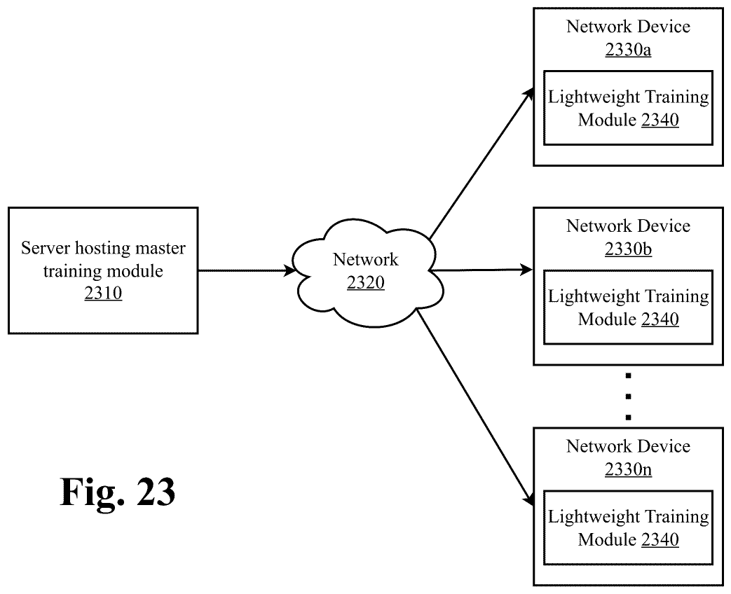

FIG. 23 is a block diagram of another embodiment of the codebook training system using a distributed architecture and a modified training module. According to an embodiment, there may be a server which maintains a master supervisory process over remote training devices hosting a master training module 2310 which communicates via a network 2320 to a plurality of connected network devices 2330a-n. The server may be located at the remote training end such as, but not limited to, cloud-based resources, a user-owned data center, etc. The master training module located on the server operates similarly to the codebook training module disclosed in FIG. 22 above, however, the server 2310 utilizes the master training module via the network device manager 2260 to farm out training resources to network devices 2330a-n. The server 2310 may allocate resources in a variety of ways, for example, round-robin, priority-based, or other manner, depending on the user needs, costs, and number of devices running the encoding/decoding system. Server 2310 may identify elastic resources which can be employed if available to scale up training when the load becomes too burdensome. On the network devices 2330a-n may be present a lightweight version of the training module 2340 that trades a little suboptimality in the codebook for training on limited machinery and/or makes training happen in low-priority threads to take advantage of idle time. In this way the training of new encoding/decoding algorithms may take place in a distributed manner which allows data gathering or generating devices to process and train on data gathered locally, which may improve system latency and optimize available network resources.

### Detailed Description of Exemplary Aspects

Since the library consists of re-usable building sourceblocks, and the actual data is represented by reference codes to the library, the total storage space of a single set of data would be much smaller than conventional methods, wherein the data is stored in its entirety. The more data sets that are stored, the larger the library becomes, and the more data can be stored in reference code form.

As an analogy, imagine each data set as a collection of printed books that are only occasionally accessed. The amount of physical shelf space required to store many collections would be quite large and is analogous to conventional methods of storing every single bit of data in every data set. Consider, however, storing all common elements within and across books in a single library, and storing the books as references codes to those common elements in that library. As a single book is added to the library, it will contain many repetitions of words and phrases. Instead of storing the whole words and phrases, they are added to a library, and given a reference code, and stored as reference codes. At this scale, some space savings may be achieved, but the reference codes will be on the order of the same size as the words themselves.

As more books are added to the library, larger phrases, quotations, and other words patterns will become common among the books. The larger the word patterns, the smaller the reference codes will be in relation to them as not all possible word patterns will be used. As entire collections of books are added to the library, sentences, paragraphs, pages, or even whole books will become repetitive. There may be many duplicates of books within a collection and across multiple collections, many references and quotations from one book to another, and much common phraseology within books on particular subjects. If each unique page of a book is stored only once in a common library and given a reference code, then a book of 1,000 pages or more could be stored on a few printed pages as a string of codes referencing the proper full-sized pages in the common library. The physical space taken up by the books would be dramatically reduced. The more collections that are added, the greater the likelihood that phrases, paragraphs, pages, or entire books will already be in the library, and the more information in each collection of books can be stored in reference form. Accessing entire collections of books is then limited not by physical shelf space, but by the ability to reprint and recycle the books as needed for use.

The projected increase in storage capacity using the method(s) herein described is primarily dependent on two factors: 1) the ratio of the number of bits in a block to the number of bits in the reference code, and 2) the amount of repetition in data being stored by the system.

With respect to the first factor, the number of bits used in the reference codes to the sourceblocks must be smaller than the number of bits in the sourceblocks themselves in order for any additional data storage capacity to be obtained. As a simple example, 16-bit sourceblocks would require 2¹⁶, or 65536, unique reference codes to represent all possible patterns of bits. If all possible 65536 blocks patterns are utilized, then the reference code itself would also need to contain sixteen bits in order to refer to all possible 65,536 blocks patterns. In such case, there would be no storage savings. However, if only 16 of those block patterns are utilized, the reference code can be reduced to 4 bits in size, representing an effective compression of 4 times (16 bits/4 bits=4) versus conventional storage. Using a typical block size of 512 bytes, or 4,096 bits, the number of possible block patterns is 2^{4,096}, which for all practical purposes is unlimited. A typical hard drive contains one terabyte (TB) of physical storage capacity, which represents 1,953,125,000, or roughly 2³¹, 512 byte blocks. Assuming that 1 TB of unique 512-byte sourceblocks were contained in the library, and that the reference code would thus need to be 31 bits long, the effective compression ratio for stored data would be on the order of 132 times (4,096/31 ≈132) that of conventional storage.

With respect to the second factor, in most cases it could be assumed that there would be sufficient repetition within a data set such that, when the data set is broken down into sourceblocks, its size within the library would be smaller than the original data. However, it is conceivable that the initial copy of a data set could require somewhat more storage space than the data stored in a conventional manner, if all or nearly all sourceblocks in that set were unique. For example, assuming that the reference codes are 1/10^{th} the size of a full-sized copy, the first copy stored as sourceblocks in the library would need to be 1.1 megabytes (MB), (1 MB for the complete set of full-sized sourceblocks in the library and 0.1 MB for the reference codes). However, since the sourceblocks stored in the library are universal, the more duplicate copies of something you save, the greater efficiency versus conventional storage methods. Conventionally, storing 10 copies of the same data requires 10 times the storage space of a single copy. For example, ten copies of a 1 MB file would take up 10 MB of storage space. However, using the method described herein, only a single full-sized copy is stored, and subsequent copies are stored as reference codes. Each additional copy takes up only a fraction of the space of the full-sized copy. For example, again assuming that the reference codes are 1/10^{th} the size of the full-size copy, ten copies of a 1 MB file would take up only 2 MB of space (1 MB for the full-sized copy, and 0.1 MB each for ten sets of reference codes). The larger the library, the more likely that part or all of incoming data will duplicate sourceblocks already existing in the library.

The size of the library could be reduced in a manner similar to storage of data. Where sourceblocks differ from each other only by a certain number of bits, instead of storing a new sourceblock that is very similar to one already existing in the library, the new sourceblock could be represented as a reference code to the existing sourceblock, plus information about which bits in the new block differ from the existing block. For example, in the case where 512 byte sourceblocks are being used, if the system receives a new sourceblock that differs by only one bit from a sourceblock already existing in the library, instead of storing a new 512 byte sourceblock, the new sourceblock could be stored as a reference code to the existing sourceblock, plus a reference to the bit that differs. Storing the new sourceblock as a reference code plus changes would require only a few bytes of physical storage space versus the 512 bytes that a full sourceblock would require. The algorithm could be optimized to store new sourceblocks in this reference code plus changes form unless the changes portion is large enough that it is more efficient to store a new, full sourceblock.

It will be understood by one skilled in the art that transfer and synchronization of data would be increased to the same extent as for storage. By transferring or synchronizing reference codes instead of full-sized data, the bandwidth requirements for both types of operations are dramatically reduced.

In addition, the method described herein is inherently a form of encryption. When the data is converted from its full form to reference codes, none of the original data is contained in the reference codes. Without access to the library of sourceblocks, it would be impossible to re-construct any portion of the data from the reference codes. This inherent property of the method described herein could obviate the need for traditional encryption algorithms, thereby offsetting most or all of the computational cost of conversion of data back and forth to reference codes. In theory, the method described herein should not utilize any additional computing power beyond traditional storage using encryption algorithms. Alternatively, the method described herein could be in addition to other encryption algorithms to increase data security even further.

In other embodiments, additional security features could be added, such as: creating a proprietary library of sourceblocks for proprietary networks, physical separation of the reference codes from the library of sourceblocks, storage of the library of sourceblocks on a removable device to enable easy physical separation of the library and reference codes from any network, and incorporation of proprietary sequences of how sourceblocks are read and the data reassembled.

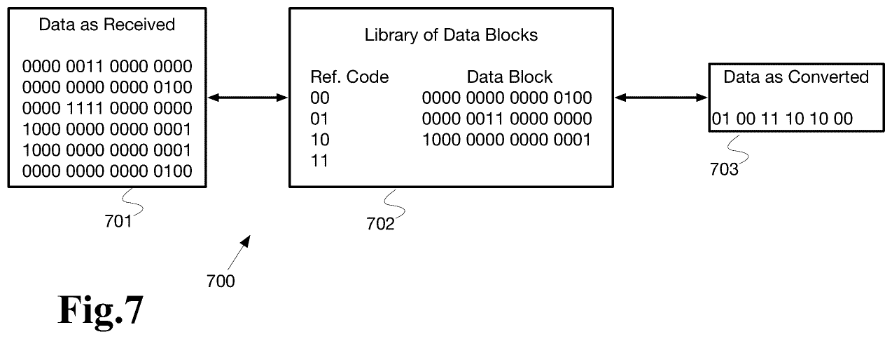

FIG. 7 is a diagram showing an example of how data might be converted into reference codes using an aspect of an embodiment 700. As data is received 701, it is read by the processor in sourceblocks of a size dynamically determined by the previously disclosed sourceblock size optimizer 410. In this example, each sourceblock is 16 bits in length, and the library 702 initially contains three sourceblocks with reference codes 00, 01, and 10. The entry for reference code 11 is initially empty. As each 16 bit sourceblock is received, it is compared with the library. If that sourceblock is already contained in the library, it is assigned the corresponding reference code. So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 703 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

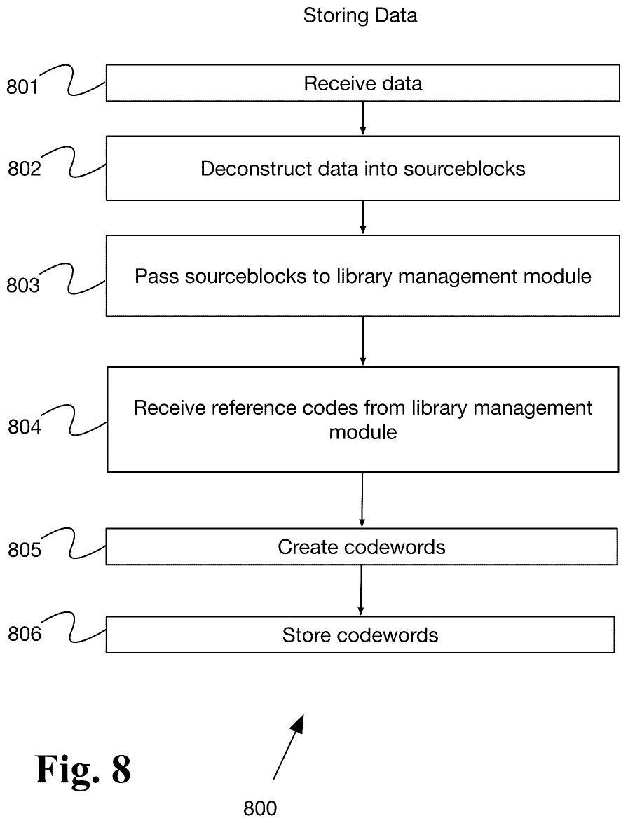

FIG. 8 is a method diagram showing the steps involved in using an embodiment 800 to store data. As data is received 801, it would be deconstructed into sourceblocks 802, and passed 803 to the library management module for processing. Reference codes would be received back 804 from the library management module and could be combined with location information to create codewords 805, which would then be stored 806 as representations of the original data.

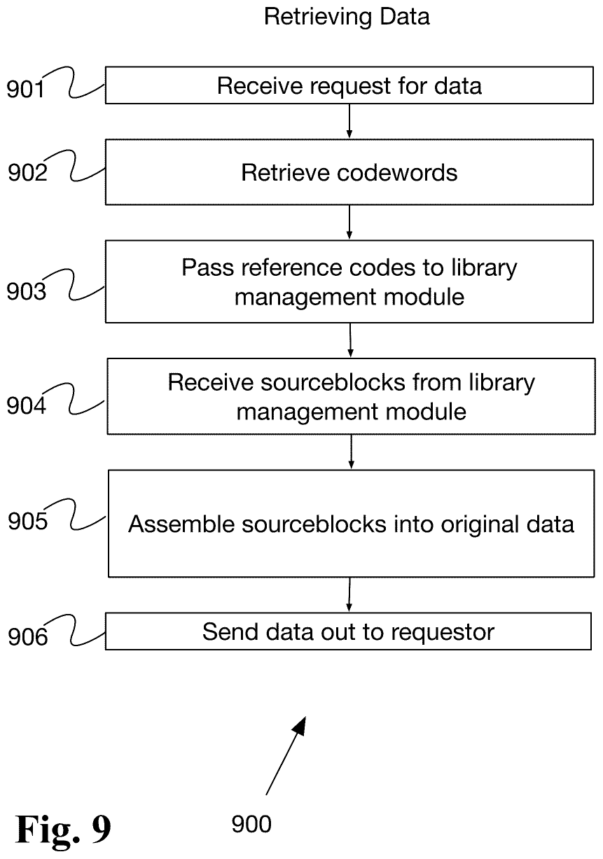

FIG. 9 is a method diagram showing the steps involved in using an embodiment 900 to retrieve data. When a request for data is received 901, the associated codewords would be retrieved 902 from the library. The codewords would be passed 903 to the library management module, and the associated sourceblocks would be received back 904. Upon receipt, the sourceblocks would be assembled 905 into the original data using the location data contained in the codewords, and the reconstructed data would be sent out 906 to the requestor.

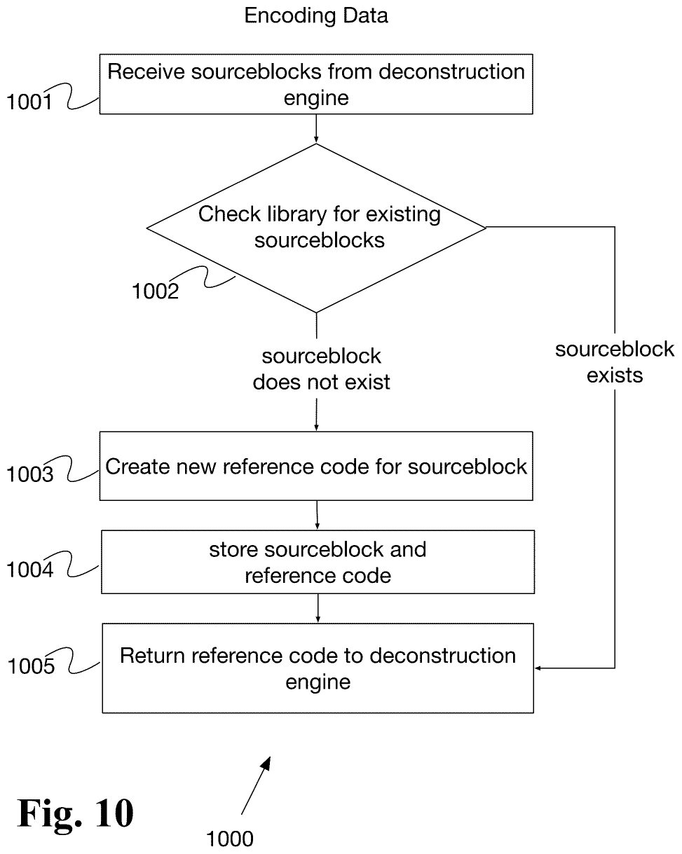

FIG. 10 is a method diagram showing the steps involved in using an embodiment 1000 to encode data. As sourceblocks are received 1001 from the deconstruction engine, they would be compared 1002 with the sourceblocks already contained in the library. If that sourceblock already exists in the library, the associated reference code would be returned 1005 to the deconstruction engine. If the sourceblock does not already exist in the library, a new reference code would be created 1003 for the sourceblock. The new reference code and its associated sourceblock would be stored 1004 in the library, and the reference code would be returned to the deconstruction engine.

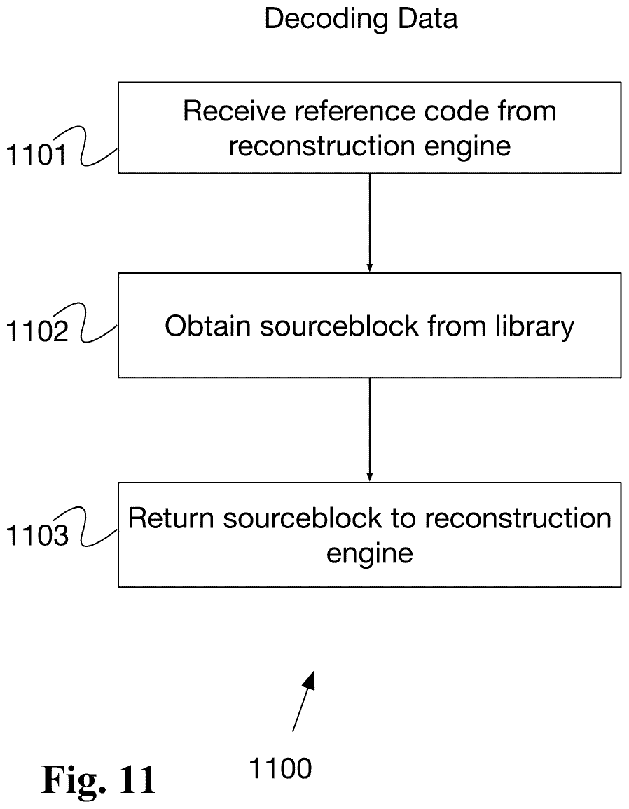

FIG. 11 is a method diagram showing the steps involved in using an embodiment 1100 to decode data. As reference codes are received 1101 from the reconstruction engine, the associated sourceblocks are retrieved 1102 from the library, and returned 1103 to the reconstruction engine.

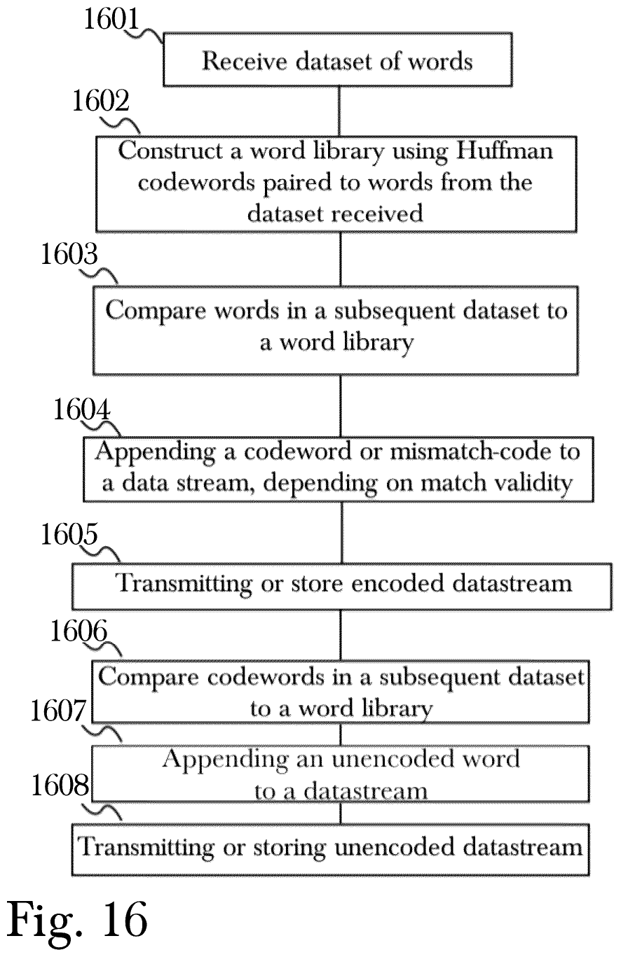

FIG. 16 is a method diagram illustrating key system functionality utilizing an encoder and decoder pair, according to a preferred embodiment. In a first step 1601, at least one incoming data set may be received at a customized library generator 1300 that then 1602 processes data to produce a customized word library 1201 comprising key-value pairs of data words (each comprising a string of bits) and their corresponding calculated binary Huffman codewords. A subsequent dataset may be received and compared to the word library 1603 to determine the proper codewords to use in order to encode the dataset. Words in the dataset are checked against the word library and appropriate encodings are appended to a data stream 1604. If a word is mismatched within the word library and the dataset, meaning that it is present in the dataset but not the word library, then a mismatched code is appended, followed by the unencoded original word. If a word has a match within the word library, then the appropriate codeword in the word library is appended to the data stream. Such a data stream may then be stored or transmitted 1605 to a destination as desired. For the purposes of decoding, an already-encoded data stream may be received and compared 1606, and un-encoded words may be appended to a new data stream 1607 depending on word matches found between the encoded data stream and the word library that is present. A matching codeword that is found in a word library is replaced with the matching word and appended to a data stream, and a mismatch code found in a data stream is deleted and the following unencoded word is re-appended to a new data stream, the inverse of the process of encoding described earlier. Such a data stream may then be stored or transmitted 1608 as desired.

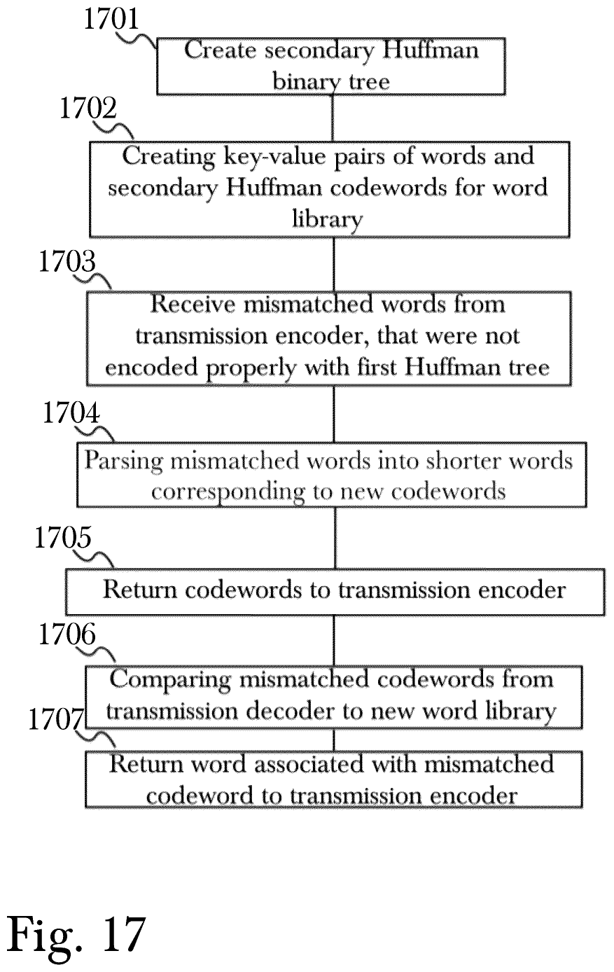

FIG. 17 is a method diagram illustrating possible use of a hybrid encoder/decoder to improve the compression ratio, according to a preferred aspect. A second Huffman binary tree may be created 1701, having a shorter maximum length of codewords than a first Huffman binary tree 1602, allowing a word library to be filled with every combination of codeword possible in this shorter Huffman binary tree 1702. A word library may be filled with these Huffman codewords and words from a dataset 1702, such that a hybrid encoder/decoder 1304, 1503 may receive any mismatched words from a dataset for which encoding has been attempted with a first Huffman binary tree 1703, 1604 and parse previously mismatched words into new partial codewords (that is, codewords that are each a substring of an original mismatched codeword) using the second Huffman binary tree 1704. In this way, an incomplete word library may be supplemented by a second word library. New codewords attained in this way may then be returned to a transmission encoder 1705, 1500. In the event that an encoded dataset is received for decoding, and there is a mismatch code indicating that additional coding is needed, a mismatch code may be removed and the unencoded word used to generate a new codeword as before 1706, so that a transmission encoder 1500 may have the word and newly generated codeword added to its word library 1707, to prevent further mismatching and errors in encoding and decoding.

It will be recognized by a person skilled in the art that the methods described herein can be applied to data in any form. For example, the method described herein could be used to store genetic data, which has four data units: C, G, A, and T. Those four data units can be represented as 2 bit sequences: 00, 01, 10, and 11, which can be processed and stored using the method described herein.

It will be recognized by a person skilled in the art that certain embodiments of the methods described herein may have uses other than data storage. For example, because the data is stored in reference code form, it cannot be reconstructed without the availability of the library of sourceblocks. This is effectively a form of encryption, which could be used for cyber security purposes. As another example, an embodiment of the method described herein could be used to store backup copies of data, provide for redundancy in the event of server failure, or provide additional security against cyberattacks by distributing multiple partial copies of the library among computers are various locations, ensuring that at least two copies of each sourceblock exist in different locations within the network.

### Hardware Architecture

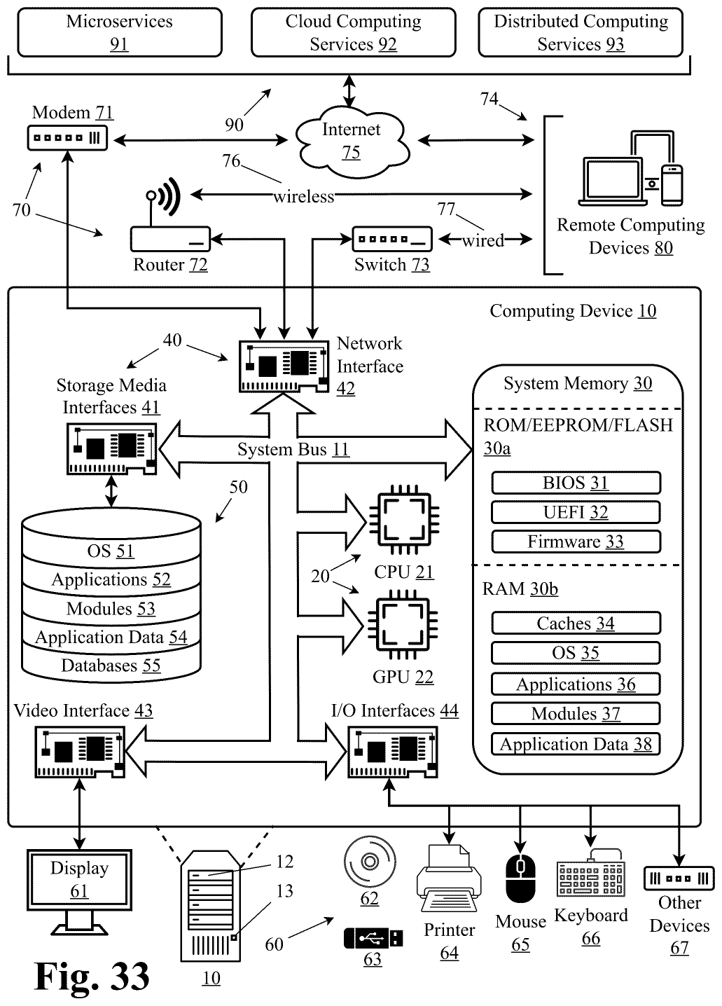

FIG. 33 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally-accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions based on technologies like complex instruction set computer (CISC) or reduced instruction set computer (RISC). Further, computing device 10 may comprise one or more specialized processors such as a graphics processing unit (GPU) 22 configured to accelerate processing of computer graphics and images via a large array of specialized processing cores arranged in parallel. Further computing device 10 may be comprised of one or more specialized processes such as Intelligent Processing Units, field-programmable gate arrays or application-specific integrated circuits for specific tasks or types of tasks. The term processor may further include: neural processing units (NPUs) or neural computing units optimized for machine learning and artificial intelligence workloads using specialized architectures and data paths; tensor processing units (TPUs) designed to efficiently perform matrix multiplication and convolution operations used heavily in neural networks and deep learning applications; application-specific integrated circuits (ASICs) implementing custom logic for domain-specific tasks; application-specific instruction set processors (ASIPs) with instruction sets tailored for particular applications; field-programmable gate arrays (FPGAs) providing reconfigurable logic fabric that can be customized for specific processing tasks; processors operating on emerging computing paradigms such as quantum computing, optical computing, mechanical computing (e.g., using nanotechnology entities to transfer data), and so forth. Depending on configuration, computing device 10 may comprise one or more of any of the above types of processors in order to efficiently handle a variety of general purpose and specialized computing tasks. The specific processor configuration may be selected based on performance, power, cost, or other design constraints relevant to the intended application of computing device 10.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed, and includes memory types such as read only memory (ROM), electronically-erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

There are several types of computer memory, each with its own characteristics and use cases. System memory 30 may be configured in one or more of the several types described herein, including high bandwidth memory (HBM) and advanced packaging technologies like chip-on-wafer-on-substrate (CoWoS). Static random access memory (SRAM) provides fast, low-latency memory used for cache memory in processors, but is more expensive and consumes more power compared to dynamic random access memory (DRAM). SRAM retains data as long as power is supplied. DRAM is the main memory in most computer systems and is slower than

SRAM but cheaper and more dense. DRAM requires periodic refresh to retain data. NAND flash is a type of non-volatile memory used for storage in solid state drives (SSDs) and mobile devices and provides high density and lower cost per bit compared to DRAM with the trade-off of slower write speeds and limited write endurance. HBM is an emerging memory technology that provides high bandwidth and low power consumption which stacks multiple DRAM dies vertically, connected by through-silicon vias (TSVs). HBM offers much higher bandwidth (up to 1 TB/s) compared to traditional DRAM and may be used in high-performance graphics cards, AI accelerators, and edge computing devices. Advanced packaging and CoWoS are technologies that enable the integration of multiple chips or dies into a single package. CoWoS is a 2.5D packaging technology that interconnects multiple dies side-by-side on a silicon interposer and allows for higher bandwidth, lower latency, and reduced power consumption compared to traditional PCB-based packaging. This technology enables the integration of heterogeneous dies (e.g., CPU, GPU, HBM) in a single package and may be used in high-performance computing, Al accelerators, and edge computing devices.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. In some high-performance computing systems, multiple GPUs may be connected using NVLink bridges, which provide high-bandwidth, low-latency interconnects between GPUs. NVLink bridges enable faster data transfer between GPUs, allowing for more efficient parallel processing and improved performance in applications such as machine learning, scientific simulations, and graphics rendering. One or more input/output (I/O) interfaces 44 provide the necessary support for communications between computing device 10 and any external peripherals and accessories 60.

For wireless communications, the necessary radio-frequency hardware and firmware may be connected to I/O interface 44 or may be integrated into I/O interface 44. Network interface 42 may support various communication standards and protocols, such as Ethernet and Small Form-Factor Pluggable (SFP). Ethernet is a widely used wired networking technology that enables local area network (LAN) communication. Ethernet interfaces typically use RJ45 connectors and support data rates ranging from 10 Mbps to 100 Gbps, with common speeds being 100 Mbps, 1 Gbps, 10 Gbps, 25 Gbps, 40 Gbps, and 100 Gbps. Ethernet is known for its reliability, low latency, and cost-effectiveness, making it a popular choice for home, office, and data center networks. SFP is a compact, hot-pluggable transceiver used for both telecommunication and data communications applications. SFP interfaces provide a modular and flexible solution for connecting network devices, such as switches and routers, to fiber optic or copper networking cables. SFP transceivers support various data rates, ranging from 100 Mbps to 100 Gbps, and can be easily replaced or upgraded without the need to replace the entire network interface card. This modularity allows for network scalability and adaptability to different network requirements and fiber types, such as single-mode or multi-mode fiber.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid state memory technology. Non-volatile data storage devices 50 may be implemented using various technologies, including hard disk drives (HDDs) and solid-state drives (SSDs). HDDs use spinning magnetic platters and read/write heads to store and retrieve data, while SSDs use NAND flash memory. SSDs offer faster read/write speeds, lower latency, and better durability due to the lack of moving parts, while HDDs typically provide higher storage capacities and lower cost per gigabyte. NAND flash memory comes in different types, such as Single-Level Cell (SLC), Multi-Level Cell (MLC), Triple-Level Cell (TLC), and Quad-Level Cell (QLC), each with trade-offs between performance, endurance, and cost. Storage devices connect to the computing device 10 through various interfaces, such as SATA, NVMe, and PCIe. SATA is the traditional interface for HDDs and SATA SSDs, while NVMe (Non-Volatile Memory Express) is a newer, high-performance protocol designed for SSDs connected via PCIe. PCIe SSDs offer the highest performance due to the direct connection to the PCle bus, bypassing the limitations of the SATA interface. Other storage form factors include M.2 SSDs, which are compact storage devices that connect directly to the motherboard using the M.2 slot, supporting both SATA and NVMe interfaces.

Additionally, technologies like Intel Optane memory combine 3D XPoint technology with NAND flash to provide high-performance storage and caching solutions. Non-volatile data storage devices 50 may be non-removable from computing device 10, as in the case of internal hard drives, removable from computing device 10, as in the case of external USB hard drives, or a combination thereof. However, computing devices will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, NoSQL databases, vector databases, knowledge graph databases, key-value databases, document oriented data stores, and graph databases.

Applications (also known as computer software or software applications) are sets of programming instructions designed to perform specific tasks or provide specific functionality on a computer or other computing devices. Applications are typically written in high-level programming languages such as C, C++, Scala, Erlang, GoLang, Java, Scala, Rust, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems facilitated by specifications such as containerd.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing device and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network or optical transmitters (e.g., lasers). Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers or networking functions may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices or intermediate networking equipment (e.g., for deep packet inspection).

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90. Also, certain processing subtasks may be sent to a microservice 91 for processing with the result being transmitted to computing device 10 for incorporation into a larger processing task. Infrastructure as Code (IaaC) tools like Terraform can be used to manage and provision computing resources across multiple cloud providers or hyperscalers. This allows for workload balancing based on factors such as cost, performance, and availability. For example, Terraform can be used to automatically provision and scale resources on AWS spot instances during periods of high demand, such as for surge rendering tasks, to take advantage of lower costs while maintaining the required performance levels. In the context of rendering, tools like Blender can be used for object rendering of specific elements, such as a car, bike, or house. These elements can be approximated and roughed in using techniques like bounding box approximation or low-poly modeling to reduce the computational resources required for initial rendering passes. The rendered elements can then be integrated into the larger scene or environment as needed, with the option to replace the approximated elements with higher-fidelity models as the rendering process progresses.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is containerd, which is widely used in software development and deployment. Containerization, particularly with open-source technologies like containerd and container orchestration systems like Kubernetes, is a common approach for deploying and managing applications. Containers are created from images, which are lightweight, standalone, and executable packages that include application code, libraries, dependencies, and runtime. Images are often built from a containerfile or similar, which contains instructions for assembling the image. Containerfiles are configuration files that specify how to build a container image. Systems like Kubernetes natively support containerd as a container runtime. They include commands for installing dependencies, copying files, setting environment variables, and defining runtime configurations. Container images can be stored in repositories, which can be public or private. Organizations often set up private registries for security and version control using tools such as Harbor, JFrog Artifactory and Bintray, GitLab Container Registry, or other container registries. Containers can communicate with each other and the external world through networking. Containerd provides a default network namespace, but can be used with custom network plugins. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, mainframe computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are serverless logic apps, microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, protobuffers, gRPC or message queues such as Kafka. Microservices 91 can be combined to perform more complex or distributed processing tasks. In an embodiment, Kubernetes clusters with containerized resources are used for operational packaging of system.

Cloud computing services 92 are delivery of computing resources and services over the Internet 75 from a remote location. Cloud computing services 92 provide additional computer hardware and storage on as-needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over public or private networks or the Internet on a subscription or alternative licensing basis, or consumption or ad-hoc marketplace basis, or combination thereof.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power or support for highly dynamic compute, transport or storage resource variance or uncertainty over time requiring scaling up and down of constituent system resources. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, NVLink or other GPU-to-GPU high bandwidth communications links and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A method for generating a full binary tree codebook using only integer operations, comprising the steps of:
collecting integer occurrence counts for a plurality of sourceblocks from a data stream;
sorting the plurality of sourceblocks by decreasing occurrence count using integer comparison operations;
initializing integer tracking variables for cumulative probability tracking and normalization;
for each sourceblock in the sorted plurality of sourceblocks:
calculating a normalized occurrence value using integer multiplication and a normalization factor;
determining a codeword length by:
approximating a logarithmic calculation using most significant bit position detection;
performing bit shift operations based on the detected bit positions; and
determining a ceiling value using integer comparison operations;
updating the integer tracking variables using addition operations and bit shifts; and
calculating a next normalization factor using integer operations to maintain a full binary tree structure;
generating a full binary tree codebook based on the determined codeword lengths, wherein the codebook is generated using only integer addition, subtraction, multiplication, and bit shift operations.

2. The method of claim 1, wherein approximating the logarithmic calculation comprises:
determining a first most significant bit position in a first integer value;
determining a second most significant bit position in a second integer value;
calculating a bit position difference between the first and second most significant bit positions; and
performing a bit shift operation based on the calculated difference.

3. The method of claim 2, further comprising the steps of:
performing a comparison operation between a bit-shifted value and an original value; and
based on the comparison result, adding an integer value of one to the bit position difference to determine the ceiling value.

4. The method of claim 1, wherein updating the integer tracking variables comprises:
calculating a power of two using a left bit shift operation based on the determined codeword length; and
adding an integer value to a running sum using integer addition.

5. The method of claim 1, wherein calculating the next normalization factor comprises:
performing integer subtraction to determine a remaining probability space;
performing integer subtraction to determine a sum of remaining sourceblock probabilities; and
calculating a ratio using integer operations without floating-point division.

6. The method of claim 1, wherein the method requires at most four integer registers beyond the occurrence counters for operation.

7. The method of claim 1, wherein the method is implemented on a microcontroller without a floating-point unit.

8. The method of claim 1, further comprising the step of:
representing the codebook in a canonical form where only the codeword length for each sourceblock is stored.

9. The method of claim 1, wherein the method produces codeword lengths that are within one bit of the information-theoretic optimal length while using only integer operations.

10. A system for generating a full binary tree codebook using only integer operations, comprising:
a processor without floating-point capabilities;
a memory storing instructions that, when executed by the processor, cause the system to:
collect integer occurrence counts for a plurality of sourceblocks from a data stream;
sort the plurality of sourceblocks by decreasing occurrence count using integer comparison operations;
initialize integer tracking variables for cumulative probability tracking and normalization;
for each sourceblock in the sorted plurality of sourceblocks:
calculate a normalized occurrence value using integer multiplication and a normalization factor;
determine a codeword length by:
approximating a logarithmic calculation using most significant bit position detection;
performing bit shift operations based on the detected bit positions; and
determining a ceiling value using integer comparison operations;
update the integer tracking variables using addition operations and bit shifts; and
calculate a next normalization factor using integer operations to maintain a full binary tree structure;
generate a full binary tree codebook based on the determined codeword lengths, wherein the codebook is generated using only integer addition, subtraction, multiplication, and bit shift operations.

11. The system of claim 10, wherein approximating the logarithmic calculation comprises:
determining a first most significant bit position in a first integer value;
determining a second most significant bit position in a second integer value;
calculating a bit position difference between the first and second most significant bit positions; and
performing a bit shift operation based on the calculated difference.

12. The system of claim 11, wherein the instructions further cause the system to:
perform a comparison operation between a bit-shifted value and an original value; and
based on the comparison result, add an integer value of one to the bit position difference to determine the ceiling value.

13. The system of claim 10, wherein updating the integer tracking variables comprises:
calculating a power of two using a left bit shift operation based on the determined codeword length; and
adding an integer value to a running sum using integer addition.

14. The system of claim 10, wherein calculating the next normalization factor comprises:
performing integer subtraction to determine a remaining probability space;
performing integer subtraction to determine a sum of remaining sourceblock probabilities; and
calculating a ratio using integer operations without floating-point division.

15. The system of claim 10, wherein the system requires at most four integer registers beyond the occurrence counters for operation.

16. The system of claim 10, wherein the system is implemented on a microcontroller without a floating-point unit.

17. The system of claim 10, wherein the instructions further cause the system to:
represent the codebook in a canonical form where only the codeword length for each sourceblock is stored.

18. The system of claim 10, wherein the system produces codeword lengths that are within one bit of the information-theoretic optimal length while using only integer operations.
